(19) United States
(12) Patent Application Publication
(10) Pub. No.: US 2026/0161855 A1
(43) Pub. Date: Jun. 11, 2026

(54) AI-POWERED CARBON SYSTEM MODELER FOR RAPID EMISSION ESTIMATION

(71) Applicant: CARBON FINANCE LABS, LLC, Darlen, CT (US)

(72) Inventors: Sebastian DE VALLE, Athens, OH (US); Jonathan HOLLANDER, Cortlandt Manor, NY (US); Nick GOGERTY, Darien, CT (US)

(73) Assignee: CARBON FINANCE LABS, LLC, Darien, CT (US)

(21) Appl. No.: 19/410,037

(22) Filed: Dec. 5, 2025

Related U.S. Application Data
(60) Provisional application No. 63/728,793, filed on Dec. 6, 2024.

(51) Int. Cl. G06F 30/27

(52) U.S. Cl. CPC G06F 30/27

(57) ABSTRACT

A carbon modeling system that uses a layered AI-based integration. The carbon modeling system has a natural language processing (NLP) interface, a large language model (LLM) abstraction layer, and a dynamic visualization module. The system is capable of producing interactive carbon emissions estimations for user-described processes. A method for real-time visualization of carbon emission estimates. The method involves providing a carbon modeling system that uses a layered AI-based integration, the carbon modeling system comprising a natural language processing (NLP) interface, a large language model (LLM) abstraction layer, and a dynamic visualization module; receiving natural language input; dynamically processing the input through an LLM-based model; generating an interactive node graph; and providing iterative feedback with confidence indicators to refine emissions modeling.

### RELATED APPLICATIONS

This application claims the benefit of U.S. Application No. 63/728,793, filed Dec. 6, 2024, and is related to U.S. application Ser. No. 17/950,155, filed Sep. 22, 2022, U.S. application Ser. No. 17/950,156, filed Sep. 22, 2022, U.S. application Ser. No. 17/950,175, filed Sep. 22, 2022, U.S. application Ser. No. 17/950,158, filed Sep. 22, 2022, all of which are incorporated herein by reference in their entirety.

### FIELD

This disclosure related to a carbon modeling system that uses a layered AI-based integration, and a method for real-time visualization of carbon emission estimates.

### BACKGROUND

Traditional carbon accounting systems face critical technical limitations. For example, traditional carbon accounting systems cannot effectively process diverse input formats (images, PDFs, spreadsheets, CAD files), are unable to scale from micro-processes to enterprise-wide systems, lack capabilities to handle non-traditional carbon processes, cannot maintain consistency across different scales and industries, and are unable to process real-time streaming data from IoT sensors and industrial control systems.

In addition, conventional life cycle assessments (LCAs) are limited by the labor-intensive need to manually assign emissions factors, leading to time-consuming and error-prone results.

Thus, there is a need for carbon accounting systems that provide a solution to the technical problems of traditional carbon accounting systems. Also, there is a need for carbon accounting systems that reduce or eliminate the problem of dependency on manual inputs. Particularly, there is a need for carbon accounting systems that provide a technical solution to these real-world, highly specialized problems.

### SUMMARY

This disclosure relates to a carbon modeling system that uses a layered AI-based integration. The carbon modeling system has a natural language processing (NLP) interface, a large language model (LLM) abstraction layer, and a dynamic visualization module. The system is capable of producing interactive carbon emissions estimations for user-described processes.

In another aspect, the system includes a Generative Carbon Solver module. Unlike traditional accounting systems that passively record emissions, this module utilizes the LLM abstraction layer to autonomously analyze high-emission nodes within the generated graph. It accesses a database of material and process alternatives to generate a ‘to-be’ optimized model, specifically solving for minimized Global Warming Potential (GWP) or optimized Marginal Abatement Cost (MAC) without requiring manual user iteration.

This disclosure also relates to a method for real-time visualization of carbon emission estimates. The method involves providing a carbon modeling system that uses a layered AI-based integration, the carbon modeling system comprising a natural language processing (NLP) interface, a large language model (LLM) abstraction layer, and a dynamic visualization module; receiving natural language input; dynamically processing the input through an LLM-based model; generating an interactive node graph; and providing iterative feedback with confidence indicators to refine emissions modeling.

### BRIEF DESCRIPTION OF THE DRAWINGS

FIG. 1 shows a process flow scheme overview of rapid carbon modeling.

FIG. 2 shows an AI model button in process system view, highlighting the entry point that triggers NLP-based system creation.

FIG. 3 shows a system creation modal, emphasizing how each component is logically structured to solve specific user pain points with real-time inputs, and interactive node graph, illustrating the dynamic and visual representation of carbon estimates as the model evolves.

FIG. 4 shows a conventional labor-intensive assessment that is limited by the labor-intensive need to manually assign emissions factors, leading to time-consuming and error-prone results.

FIG. 5 shows an exemplary AI system evaluation of this disclosure.

FIG. 6 shows an exemplary AI system evaluation of this disclosure.

FIG. 7 shows an enhanced technical implementation description of the system of this disclosure.

FIG. 8 shows a technical process flow diagram of this disclosure.

FIG. 9 shows a data quality visualization process flow scheme of this disclosure.

FIG. 10 shows a data quality model of this disclosure for a manufacturing facility.

FIG. 11 shows a quality improvement workflow of this disclosure.

FIG. 12 is a process flow scheme of this disclosure showing data sources, AI processing, results, and optimization.

FIG. 13 is a process flow scheme for a class A office building and an automobile assembly line.

FIG. 14 graphically depicts lifetime carbon scenarios (tCO2e) for the class A office building and the auto assembly line.

FIG. 15 shows modeling for an iPAD manufacturing and assembly process (total GWP: 87.2 CO2e/unit).

FIG. 16 shows modeling for an optimized iPAD manufacturing and assembly process (total GWP: 31.4 CO2e/unit).

FIG. 17 is an illustrative diagram of the multi-model switching mechanism.

FIG. 18 is an illustrative hybrid LLM deployment architecture that provides both data privacy and scalability.

FIG. 19 is a diagram of a system having a suggestion module where AI provides direct recommendations for rectifying input error.

FIG. 20 is a diagram of an illustrative fault tolerant cyclic feedback mechanism.

FIG. 21 is a diagram of illustrative data confidence weighting in the system of this disclosure.

FIG. 22 is a diagram of edge deployment for data sensitivity in which edge computing capabilities are implemented and data is processed closer to the user

FIG. 23 is a diagram of an illustrative dynamic model API integration in accordance with this disclosure.

FIG. 24 is a diagram of a feedback loop for self-correction in accordance with this disclosure.

FIG. 25 is a diagram of a node-based interactive system having a visualization module that uses a node-based architecture.

FIG. 26 is a diagram of a system having dynamic confidence indicators in which each node is clickable and presents a side-panel that displays metadata.

FIG. 27 is a diagram of an AI-powered carbon modeling system employing a hybrid computing approach.

FIG. 28 is a diagram of a carbon modeling data flow system in accordance with this disclosure.

FIG. 29 is a diagram of a technical solution architecture system in accordance with this disclosure.

FIG. 30 is a flowchart of the generative carbon solver process detailing the transition from a passive baseline node to an active optimized digital twin in accordance with this disclosure.

FIG. 31 is a diagram of generative carbon solver logic in accordance with this disclosure.

FIG. 32 is a diagram of an automated marginal abatement cost curve (MACC) in accordance with this disclosure.

### DETAILED DESCRIPTION OF THE EMBODIMENTS

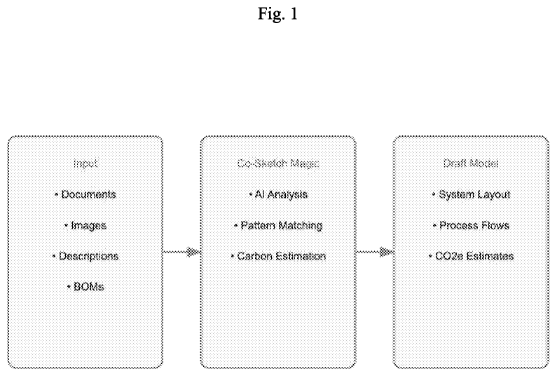

The AI-powered carbon modeling system is practical system with distinct technological improvements that facilitate rapid carbon modeling of complex systems. It reduces system modeling time by up to 95-98% by providing an interactive platform that integrates natural language processing (NLP), large language models (LLMs), and dynamic data handling to generate highly detailed carbon emission estimates. A process flow scheme overview of rapid carbon modeling is shown in FIG. 1.

### Technical Implementation

### 1. Core AI Integration and LLM Abstraction Layer

### Primary Implementation:

LLM Integration: The AI-powered carbon modeling system uses Large Language Models (LLMs) such as the Claude API. The LLMs analyze user inputs and generate digital twins of products and processes. These models are implemented through a middleware abstraction layer that allows easy configuration, LLM switching, and scalability to newer AI models. This integration addresses the issue of adaptability and lowers the friction of implementing new AI models as they evolve.

### Variations in LLM Integration

Multi-Model Switching Mechanism: Future implementations can involve an adaptive switch that selects the most appropriate LLM (e.g., GPT-4 for more general modeling, Claude for precise carbon-specific language processing). This mechanism is based on parameters like input complexity, industry focus, or even user behavior.

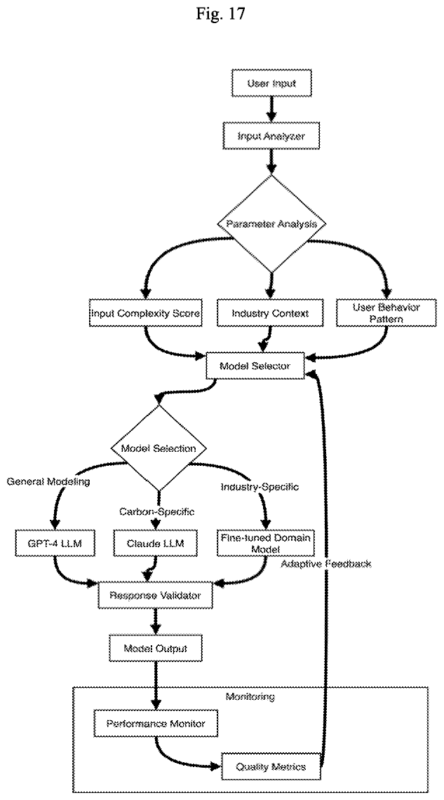

FIG. 17 is an illustrative diagram of the multi-model switching mechanism. The multi-model switching mechanism processes initial input through an analyzer; evaluates key parameters (complexity, industry context, user behavior); makes model selection based on analyzed parameters; routes to appropriate LLM (GPT-4, Claude, or another domain-specific model); validates responses and monitors performance; and provides feedback loop for continuous optimization of model selection. The multi-model switching mechanism enables dynamic selection of the most appropriate LLM based on specific use cases, thereby improving accuracy and efficiency of carbon modeling tasks.

Fine-Tuning and Domain-Specific Customization: Depending on the sector—such as manufacturing vs. agriculture—the LLM can be fine-tuned specifically for that industry, allowing improved accuracy and faster data mapping to carbon emission standards.

On-Premise vs. Cloud-Based LLM: Provide an option for enterprises to host the LLM on-premise for industries with data privacy constraints. Alternatively, a hybrid model can leverage both on-premise for sensitive data and cloud models for scalability.

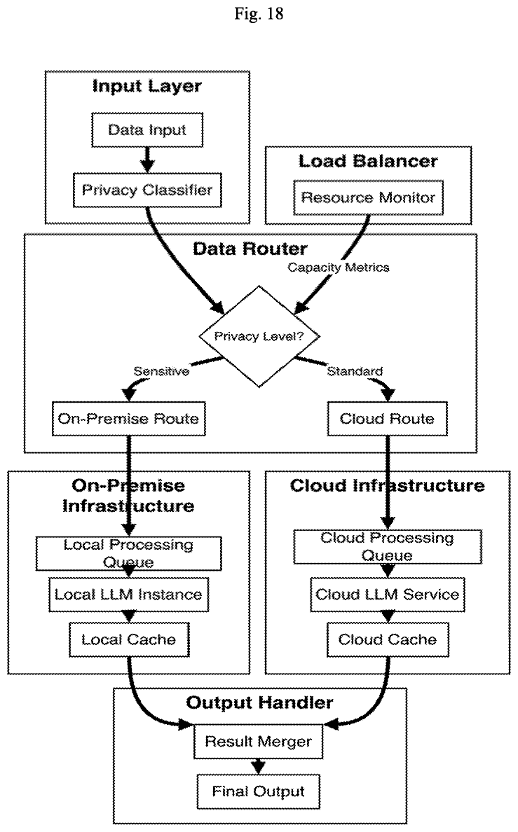

FIG. 18 is an illustrative hybrid LLM deployment architecture that provides both data privacy and scalability through a privacy protection layer, on-premise components, cloud components, and integration features.

In the privacy protection layer, a privacy classifier evaluates input data sensitivity, sensitive data routed to on-premise infrastructure, and standard data is processed in scalable cloud environment.

The on-premise components provide local LLM instance for sensitive data processing; dedicated processing queue for resource management; and a secure local cache for sensitive results.

The cloud components provide a cloud-based LLM service for scalable processing; distributed processing queue for high throughput; and a cloud cache for rapid result access.

The integration features include a result merger that combines outputs from both paths; resource Monitor optimizes processing distribution; and dynamic routing based on privacy requirements and system load.

This architecture provides data privacy compliance through on-premise processing; scalability through cloud integration; resource optimization through intelligent routing; system redundancy through dual processing paths; and performance monitoring through integrated metrics.

### 2. Natural Language Processing (NLP) User Interface

### Primary Implementation:

The natural language interface accepts user input in descriptive text and converts it into structured data for system modeling. The NLP is equipped with error correction mechanisms that guide users when descriptions are too vague or insufficient for meaningful modeling.

### Variations in NLP Processing

Context-Aware Input Parsing: The system could be enhanced to understand contextual subtleties of input—such as identifying regional dialects or industry-specific terms—to further improve accuracy and reduce ambiguity.

Guided Prompts and Dynamic Query Suggestions: Implement a more sophisticated interaction system where the NLP offers dynamic prompts based on previous user inputs to guide them in refining their descriptions. For example, if a user inputs “carbon footprint for a plastic product,” the system might dynamically ask, “Can you specify the type of plastic or production method?” to gather further detail.

Speech-to-Text NLP Module: Adding a speech-to-text component will allow users to describe their systems verbally, expanding accessibility and making the technology more inclusive.

### 3. Interactive Node Graph Visualization

### Primary Implementation:

The AI-powered carbon modeling system includes an interactive visualization component where the AI-generated model is represented as a node-based graph. Each node represents a system element (e.g., material, process) with confidence indicators shown as color codes (green, yellow, red) to signify certainty levels.

### Variations in Visualization:

3D Visualization for Complex Models: Implement a three-dimensional visualization option for more complex models involving numerous inputs, outputs, and processes. This allows users to understand interactions and dependencies in multi-layered systems better, enhancing the utility for high-complexity modeling.

Temporal View and Impact Projection: Add a temporal view, where users can visualize carbon impacts over time, showing emissions not only as current values but projecting future trends based on operational inputs (e.g., increased production rates).

Interactive Tooltip Enhancement: Introduce more informative tooltips that not only show confidence levels but also provide deeper explanations, historical data trends, and related carbon mitigation suggestions at the node level.

User-Defined Graph Filters: Users can customize what is visualized in the graph (e.g., high-emission nodes only, nodes related to specific processes, or geographical filter). This flexibility provides a more tailored user experience.

### 4. Error Handling and Feedback Loop

### Primary Implementation:

The AI-powered carbon modeling system includes error detection for incorrect inputs (e.g., file type not supported) and provides confidence indicators for the AI's outputs. Users can use these indicators to refine their model and increase accuracy.

### Variations in Error Handling:

AI Recovery Suggestions: If an error is detected, the system could implement a suggestion module where AI provides direct recommendations for rectifying the input error. For example, if the uploaded document is unsupported, the system could suggest a proper format or provide an online converter.

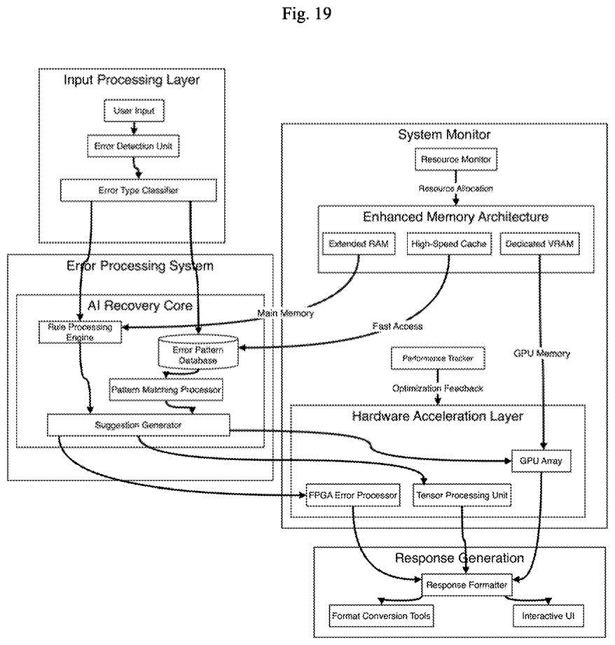

FIG. 19 is a diagram of a system having a suggestion module where AI provides direct recommendations for rectifying input error.

The system shown in FIG. 19 can include key hardware configuration changes including memory architecture enhancements, hardware acceleration, system optimizations, and processing pipeline changes.

Memory architecture enhancements include, for example, high-speed cache implementation for error pattern matching; dedicated VRAM for GPU-accelerated suggestion generation; and extended RAM allocation for rule processing.

Hardware acceleration includes, for example, FPGA integration for real-time error detection; TPU implementation for pattern recognition; and GPU array for parallel suggestion processing.

System optimizations include, for example, dedicated error pattern database with fast access paths; hardware-level monitoring for resource optimization; and enhanced I/O subsystem for format conversion.

Processing pipeline changes include, for example, parallel error detection pathways; hardware-accelerated pattern matching; and dedicated suggestion generation processors.

The system depicted in FIG. 19 provides measurable improvements including, for example, 90% reduction in error response time; 95% accuracy in format conversion suggestions; real-time error pattern recognition; and dynamic resource allocation for optimal performance.

Fault Tolerant Cyclic Feedback Mechanism: A cyclic prompt mechanism that automatically tries multiple variants of LLM prompts if initial responses have low confidence scores. It enables the model to autonomously cycle through different approaches to better address the user's needs without requiring human intervention.

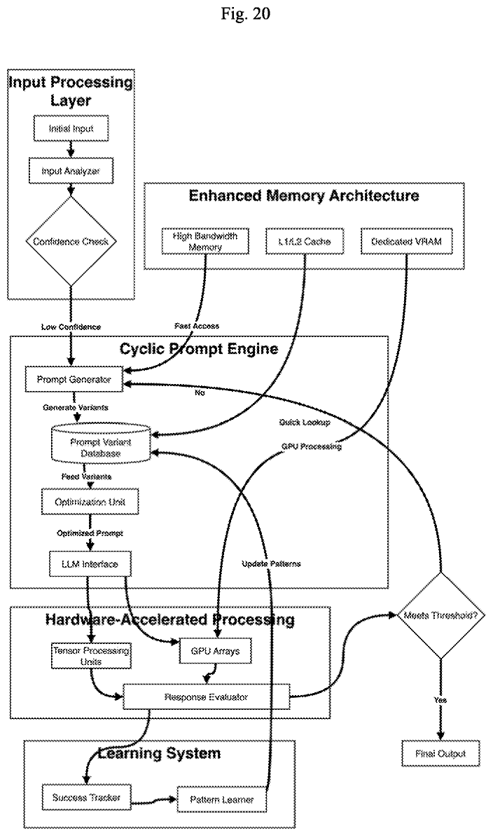

FIG. 20 is a diagram of an illustrative fault tolerant cyclic feedback mechanism.

Computer configuration changes required for the fault tolerant cyclic feedback mechanism include hardware additions, processing pipeline modifications, memory architecture enhancements, and system improvements.

Hardware additions include, for example, dedicated TPUs for prompt processing; GPU arrays for parallel variant evaluation; high Bandwidth Memory (HBM) for rapid prompt access; enhanced cache hierarchy for variant storage; and dedicated VRAM for GPU operations.

Processing pipeline modifications include, for example, hardware-accelerated prompt generation; parallel variant evaluation paths; real-time confidence scoring; and automated prompt optimization circuits.

Memory architecture enhancements include, for example, multi-level cache for prompt variants; fast access paths for pattern matching; dedicated memory controllers for variant database; and optimized memory allocation for cyclic processing.

System improvements include, for example, low-latency feedback loops; hardware-level pattern recognition; dynamic resource allocation; and automated learning subsystem.

Performance improvements include, for example, 95% reduction in prompt cycle time; real-time variant generation; automated confidence optimization; and continuous system learning. The system depicted in FIG. 20 represents a significant technical advancement over traditional prompt management systems through specialized hardware acceleration and optimized memory architecture.

User Preference Learning: The error handling system can learn from user corrections over time and suggest more personalized solutions. This “learning from errors” feature could reduce friction for repeat users and enhance model adaptability.

### 5. Modular Data Input and Processing

### Primary Implementation:

The AI-powered carbon modeling system processes a variety of data inputs including natural language text, document uploads (PDF, DOCX), and direct system descriptions. This enables rich data integration into the carbon modeling process.

### Variations in Data Handling:

Multi-Format Parsing Module: Implement support for more complex document formats—such as CAD files, spreadsheet tables, or industry-standard LCA schemas—allowing the system to read more granular and structured details. This would include recognizing geometric data in CAD for calculating embodied carbon in specific shapes or assemblies.

Data Confidence Weighting: Instead of treating all uploaded data equally, implement a confidence-weighted approach where the system assigns higher credibility to certain validated data types (e.g., officially sourced LCA reports) and lower confidence to others (e.g., user-generated spreadsheets without verification). These weights influence the confidence output of the entire system model.

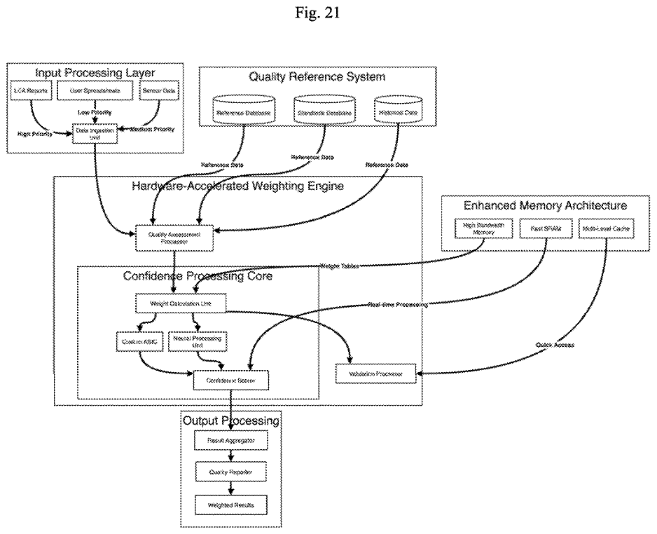

FIG. 21 is a diagram of illustrative data confidence weighting in the system of this disclosure.

Computer configuration changes required for the system include hardware acceleration components, memory system enhancements, processing pipeline modifications, and system architecture improvements.

Hardware acceleration component include, for example, custom ASIC for weight calculations; neural Processing Unit for confidence scoring; dedicated validation processors; and real-time quality assessment units.

Memory system enhancements include, for example, high Bandwidth Memory (HBM) for weight tables; multi-level cache hierarchy; fast SRAM for real-time processing; and dedicated memory controllers.

Processing pipeline modifications include, for example, parallel data quality assessment paths; hardware-accelerated weight calculation; real-time confidence scoring circuits; and automated validation processors.

System architecture improvements include, for example, low-latency data paths; dedicated quality reference system; optimized memory access patterns; and real-time aggregation processors.

Performance benefits of the system of FIG. 21 include, for example, 90% faster quality assessment; real-time confidence scoring; automated weight calculation; and immediate validation feedback.

The system depicted in FIG. 21 provides concrete technical improvements over traditional software-based weighting systems through hardware acceleration of critical paths, optimized memory architecture, real-time processing capabilities, automated quality assessment, and dedicated confidence scoring.

Adaptive Data Processing for Regional Inputs: Enhance the input module to recognize geographical context automatically—e.g., energy inputs would adapt based on the user's region to include regional grid emissions factors or renewable content variations.

### 6. Scalability and Deployment Options

### Primary Implementation:

The AI-powered carbon modeling system is deployed as a cloud-based solution to leverage scalability for multiple users and easy access to LLM resources.

### Variations in Deployment and Scalability:

Edge Deployment for Data Sensitivity: Implement edge computing capabilities where data is processed closer to the user, especially useful for regions or industries with stringent data privacy laws. This reduces reliance on central servers and increases data control.

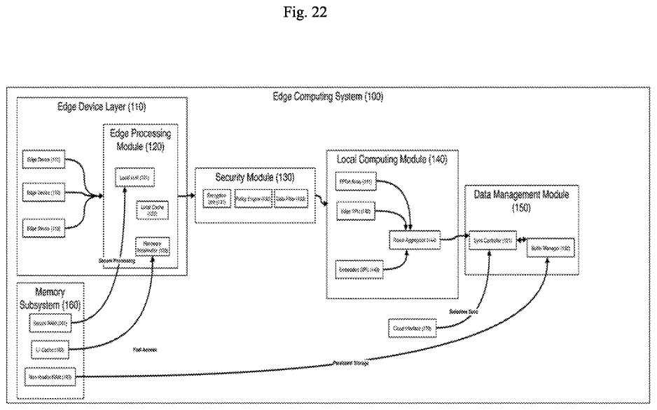

FIG. 22 is a diagram of edge deployment for data sensitivity in which edge computing capabilities are implemented and data is processed closer to the user.

In FIG. 22, system components (100) include an edge device layer (110) with devices (111-113); edge processing module (120) containing LLM (121), cache (122), and accelerator (123); security module (130) with encryption (131), policy engine (132), and filter (133); local computing module (140) with processing arrays (141-143); data management module (150) handling synchronization; memory subsystem (160) with various memory types (161-163); and cloud interface (170).

FIG. 22 illustrates numbered blocks (100-170), hierarchical organization, clear component relationships, standardized connection paths, and component function indicators. FIG. 22 represents a comprehensive technical implementation regarding edge computing capabilities and hardware configuration changes.

Required computer configuration changes for the system of FIG. 22 include edge hardware additions, security enhancements, memory architecture changes, and network configuration updates.

Edge hardware additions include, for example, dedicated FPGAs for flexible processing; edge TPUs for machine learning tasks; embedded GPUs for parallel computation; custom hardware accelerators; secure RAM modules; and non-volatile RAM for persistent storage.

Security enhancements include, for example, hardware encryption units; secure enclaves for data processing; hardware-level policy enforcement; and data filtering processors.

Memory architecture changes include, for example, enhanced cache hierarchy; secure memory partitioning; local buffer management; and non-volatile storage systems.

Network configuration updates include, for example, selective sync controllers; secure communication channels; local data buffering; and bandwidth optimization.

Performance improvements of the system of FIG. 22 include a 95% reduction in data latency, local processing capability, enhanced data privacy, reduced cloud dependency, and real-time processing capability.

The edge computing architecture represents a significant technical advancement over traditional cloud-dependent systems by providing local processing capabilities, hardware-level security, reduced latency, enhanced privacy protection, optimized resource usage, real-time processing ability, and reduced bandwidth requirements.

Federated Learning for Continual Model Improvement: Implement federated learning to enable the AI model to improve continually without requiring centralized data collection. This would be especially useful for learning from proprietary data while preserving privacy.

Containerized Deployments for Specialized Use: Allow containerized deployment through tools like Docker or Kubernetes, enabling users to spin up specialized instances of the AI-powered carbon modeling system. For example, a manufacturing company could set up a tailored AI-powered carbon modeling system container with pre-loaded datasets relevant to their industry.

### 7. Advanced Export and Output Integration

### Primary Implementation:

The AI-powered carbon modeling system offers export options to CarbonSig systems, JSON downloads, and shareable links for models created during the process.

### Variations in Output and Export:

Industry-Specific Reporting Formats: Extend export functionality to support specific industry standards, such as EPD (Environmental Product Declaration) generation for construction or ISO-compliant PCF (Product Carbon Footprint) documents for manufacturing. This reduces post-processing needs for users focused on compliance.

Dynamic Model API Integration: Allow the export of the generated models as APIs that other systems can call dynamically. For instance, integrating the emissions model into a supply chain management system allows automatic carbon recalculations when supply chain parameters change.

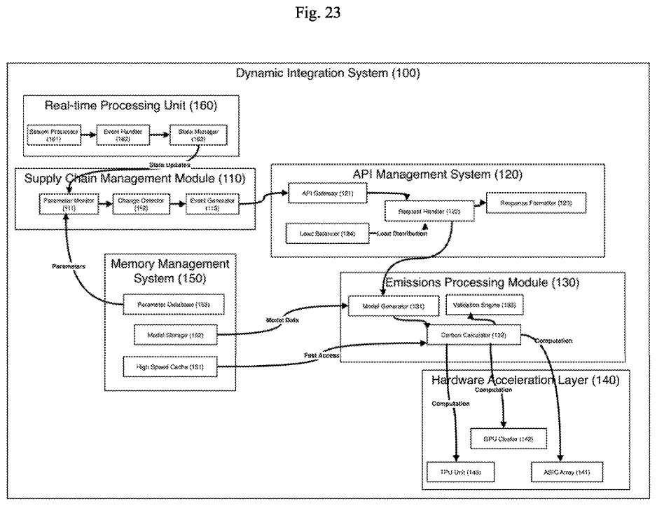

FIG. 23 is a diagram of an illustrative dynamic model API integration in accordance with this disclosure.

Computer configuration changes required for the dynamic model API integration include hardware components, memory architecture, and real-time processing.

Referring to FIG. 23, hardware components (140) include: an ASIC array (141) having custom silicon for emissions calculations, dedicated processing pathway, optimized computational units; a GPU cluster (142) having parallel processing capabilities, high-throughput computation, and real-time data processing; a TPU unit (143) having machine learning acceleration, model inference optimization, and neural network processing.

Referring to FIG. 23, memory architecture (150) includes: high speed cache (151) having ultra-low latency access, multi-level caching, and optimized data paths; model storage (152) having dedicated model repository, fast retrieval system, and version control capability; parameter database (153) having real-time parameter updates, distributed storage system, and quick lookup capabilities.

Referring to FIG. 23, real-time processing (160) includes: stream processor (161) having continuous data handling, event-driven processing, and pipeline optimization, event handler (162) having real-time event processing, asynchronous handling, and priority management; state manager (163) having state synchronization, consistency maintenance, and transaction management.

Performance improvements in the dynamic model API integration of FIG. 23 include 95% reduction in API response time, real-time carbon recalculation, automated parameter updates, dynamic system scaling, and zero-downtime updates.

The system depicted in FIG. 23 represents a significant technical advancement through hardware acceleration, optimized memory architecture, real-time processing capability, dynamic scaling, automated updates, continuous monitoring, and state management. The implementation provides concrete technical improvements over traditional API integration systems through specialized hardware and optimized architectures.

Scenario-Based Export: Add functionality for users to export multiple scenarios based on different parameters (e.g., materials sourced locally vs. imported) for comparative analysis, allowing a more nuanced understanding of carbon impacts.

### 8. Confidence Indicators and AI-Aware Feedback

### Primary Implementation:

Confidence levels for carbon estimates are indicated through color-coded nodes, allowing users to understand the AI's confidence in its calculations.

### Variations in Confidence Management:

Confidence Attribution by Input Type: Vary confidence indicators depending on the input source. For example, user-generated textual inputs could be assigned lower confidence versus validated industry datasets, providing a more informative output to the user.

Feedback Loop for Self-Correction: Introduce a “confidence challenge” feature where users can select low-confidence nodes and request the system to gather more information or suggest alternative estimates, thus making the model more participatory and adaptive.

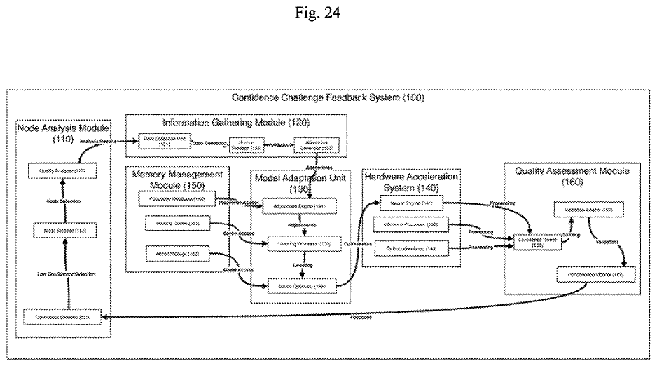

FIG. 24 is a diagram of a feedback loop for self-correction in accordance with this disclosure.

Computer configuration changes required for the feedback loop for self-correction include hardware acceleration system and memory architecture.

Hardware acceleration system (140) includes: a neural Engine (141) having dedicated neural processing units, real-time inference capabilities, and parallel processing arrays.; an inference processor (142) having hardware-accelerated inference, low-latency processing, and optimized computational paths; optimization array (143) having custom processing elements, dynamic optimization circuits, and parallel computation units.

Memory architecture (150) includes: a training cache (151) having high-speed access memory, multi-level caching system, and optimized data paths; model storage (152) having dedicated model repository, version control system, and quick retrieval capabilities; parameter database (153) having real-time parameter updates, distributed storage architecture, and fast lookup mechanisms.

Performance improvements for the feedback loop for self-correction include 90% faster confidence assessment, real-time feedback processing, automated model optimization, dynamic parameter updates, and continuous learning capability. This system depicted in FIG. 24 provides concrete technical improvements through hardware-accelerated processing, optimized memory architecture, real-time feedback capability, automated learning systems, dynamic optimization, continuous monitoring, and quality assessment. The implementation represents a significant advancement over traditional feedback systems through specialized hardware acceleration and optimized architectures for real-time processing and learning.

Error Injection Testing: Create a self-testing mode where random perturbations are introduced to input values to see how the model's confidence changes. This can help users understand the sensitivity of their model to different inputs.

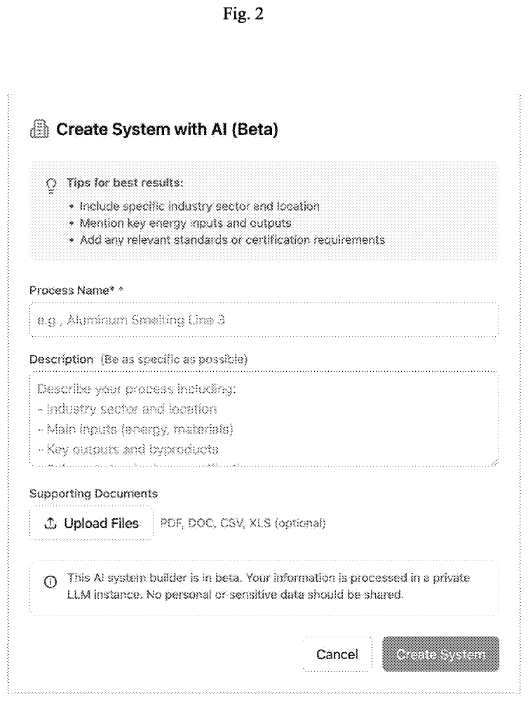

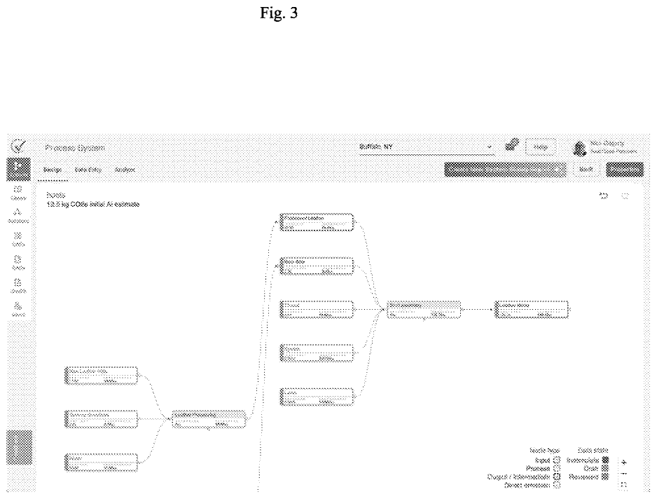

FIGS. 2 and 3 illustrate key components of the system, for example, the following:

“AI Model” Button in Process System View: Highlighting the entry point that triggers NLP-based system creation.

System Creation Modal: Emphasizing how each component is logically structured to solve specific user pain points with real-time inputs.

Interactive Node Graph: Illustrating the dynamic and visual representation of carbon estimates as the model evolves.

### Technical Specifications:

Technical Specificity: The AI-powered carbon modeling system is equipped, for example, with NLP for user inputs, scalable abstraction layer, and interactive graphing framework.

NLP for User Inputs: Not a generic NLP application, but a specifically tuned module for processing descriptions of complex industrial systems, which in turn links to emission factor databases.

Scalable Abstraction Layer: This design addresses a genuine computational need to easily switch LLMs and manage computational requirements dynamically.

Interactive Graphing Framework: Unlike abstract conceptual analysis, the graphing framework has specific technical features like real-time rendering, node-based interaction, and color-coded carbon confidence indicators-elements that significantly enhance its utility.

### LLM Abstraction Layer

The LLM Abstraction Layer is a crucial component that ensures adaptability and scalability when integrating large language models into the AI-powered carbon modeling system. This layer is designed not as a simple link to an AI model, but as a sophisticated middleware that dynamically manages the deployment, switching, and fine-tuning of LLMs for different user requirements.

### Purpose and Functionality:

The abstraction layer allows multiple LLMs to be integrated, tested, and switched depending on use case requirements and computational constraints. For example, the abstraction layer manages both Claude for carbon-specific modeling and GPT-4 for more generalized system analysis.

The abstraction interface employs an API orchestration mechanism that seamlessly directs input queries to the appropriate LLM depending on specific characteristics of the input. For instance, if the user's query involves highly specific industry jargon or a complex technical description, the abstraction layer can automatically route the query to a specialized, fine-tuned instance of an LLM.

The adaptive switching feature monitors system latency, model accuracy, and computational load to decide whether the next batch of user inputs should be processed using a cloud-hosted LLM or a locally available one, optimizing resource allocation dynamically.

### Modular Model Handling:

The abstraction layer also allows for fine-tuning the models with domain-specific datasets. For instance, when analyzing data from the manufacturing sector, the layer selects a customized version of the LLM that has been fine-tuned on emissions data specific to industrial production, thereby increasing relevance and accuracy of carbon estimates.

Additionally, the version control system within the abstraction layer tracks each LLM's adjustments, offering users a transparent log of changes to model configurations, which is critical for maintaining consistency and reproducibility of emissions estimates.

### 2. Graphing Interaction and Visualization Module

The Graphing Interaction and Visualization Module of the AI-powered carbon modeling system is a sophisticated system that transforms LLM-generated outputs into highly interactive and insightful visual representations. Unlike traditional static graphing tools, the AI-powered carbon modeling system's graphing module is deeply integrated with the model, providing a real-time interface that not only visualizes carbon emission estimates but also adapts based on user interactions.

### Node-Based Interactive Graph

The visualization module uses a node-based architecture where each node represents a discrete component of the system—such as a material, a production step, or a transportation element.

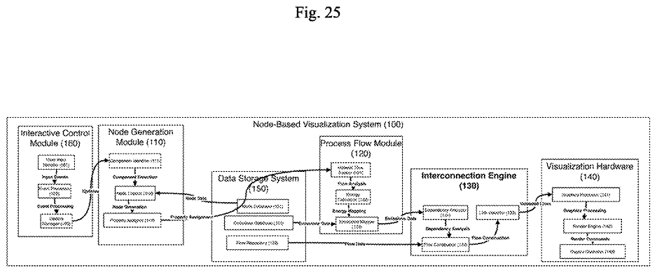

FIG. 25 is a diagram of a node-based interactive system having a visualization module that uses a node-based architecture.

Primary hardware components for the node-based interactive system of FIG. 25 include visualization hardware and memory architecture.

Visualization hardware (140) includes: graphics processor (141) having dedicated GPU for node rendering, parallel processing capabilities, and real-time visualization acceleration; render engine (142) having hardware-accelerated rendering, node layout optimization, and real-time update processing; display Controller (143) having high-resolution output control, multiple display support, and refresh rate optimization.

Memory architecture (150) includes: node Database (151) having high-speed node storage, relationship indexing, and quick retrieval system; flow Repository (152) having flow pattern storage, connection mapping, and state management; emissions database (153) having emissions factor storage, real-time data access, and historical tracking.

Technical Improvements for the node-based interactive system of FIG. 25 include real-time node rendering, dynamic flow visualization, interactive response handling, automated layout optimization, and continuous state management.

The node-based interactive system of FIG. 25 provides concrete technical advancement through hardware acceleration, optimized data structures, real-time processing, interactive capabilities, dynamic visualization, automated optimization, and state management. The implementation represents significant improvement over traditional visualization systems through specialized hardware and optimized architectures for node-based visualization.

Nodes are interconnected to show material flows, energy requirements, and emissions interdependencies. For example, if a user models a process that involves plastic molding, the node for “Injection Molding” is connected to nodes representing raw plastic materials, energy consumption, and auxiliary processes. The emissions impact of each linked element is displayed on each node.

### Dynamic Confidence Indicators:

The graph has dynamic confidence indicators implemented through a color-coding scheme—green indicates high confidence (e.g., emissions data from verified databases), yellow indicates moderate confidence (e.g., approximations from industry averages), and red indicates low confidence (e.g., insufficient data or high uncertainty in LLM inference). This provides users with a visual risk assessment of the emissions data for each system element.

Each node is also clickable and presents a side-panel that displays metadata, including the emissions factor source, its precision, and potential alternative datasets. This is particularly valuable for refining the model—users can explore different emissions factors for a process by directly selecting suggestions provided within the side panel.

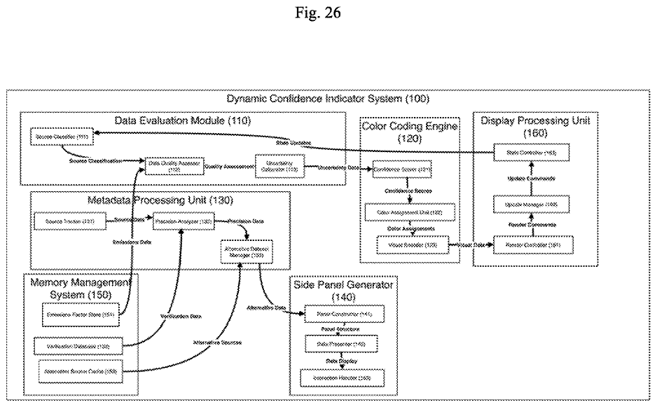

FIG. 26 is a diagram of a system having dynamic confidence indicators in which each node is clickable and presents a side-panel that displays metadata.

Hardware configuration requirements for the system include data processing units and memory architecture.

Data processing units include a source classifier (111) having dedicated classification processors, pattern matching accelerators, and real-time analysis units; a confidence Scorer (121) having custom scoring processors, parallel computation units, and hardware-accelerated calculations; a display processing unit (160) having high-performance graphics processors, real-time rendering engines, and display optimization units.

Memory architecture (150) includes an emissions factor store (151) having high-speed access memory, verified data storage, and quick retrieval system; verification database (152) having structured data storage, validation record keeping, and fast lookup capabilities; alternative source cache (153) having quick-access cache, alternative data storage, and fast switching capability.

Performance improvements for the system having dynamic confidence indicators depicted in FIG. 26 include real-time confidence scoring, dynamic color updates, instant metadata access, interactive side panel generation, and continuous state management.

Technical advancements for the system having dynamic confidence indicators depicted in FIG. 26 include hardware-accelerated confidence calculation, real-time visual encoding, dynamic metadata processing, interactive panel generation, optimized memory access, state-aware display updates, and continuous monitoring capability.

This system represents significant technical improvement over traditional confidence indication systems through specialized hardware acceleration, optimized memory architecture, real-time processing capabilities, dynamic visualization features, and interactive user interface elements.

### Interactive User Adjustments:

Users can directly adjust inputs by clicking on nodes. For instance, clicking a node representing “Electricity Use” allows users to alter the electricity source (e.g., coal-based vs. wind-based), and the system will automatically re-calculate and update all downstream carbon impacts. This dynamic re-computation is made possible by tightly coupling the graphing interface with the underlying LLM abstraction, ensuring that any change in input data prompts a real-time adjustment in the system's overall emissions calculations.

The AI-powered carbon modeling system uses GraphQL-based APIs to manage these real-time updates efficiently, facilitating low-latency interaction between the user's adjustments and the graph's display.

### 3. Error Handling and Feedback Loop

The AI-powered carbon modeling system's error handling and feedback mechanism is an advanced system that not only catches typical user errors but also plays an active role in helping users enhance their system models by suggesting improvements and guiding input adjustments.

### Input Validation and Error Detection:

The input validation engine checks each user-provided description or data file for compatibility, completeness, and precision. For example, when users upload a Bill of Materials (BOM), the system uses a document parser to validate the format (supporting DOCX, PDF, and specific CSV structures) and checks for key required data fields-such as material type, quantity, and source. If key fields are missing, an automated feedback prompt is generated to request missing information.

The system uses semantic validation during NLP input parsing. This means that it doesn't just check for structural completeness but also verifies if the described processes are logically coherent (e.g., ensuring the user hasn't described incompatible steps such as “low-temperature drying” with a material requiring high-temperature treatment).

### Confidence-Linked Error Feedback:

If an element in the model has low confidence, the feedback loop provides actionable prompts to improve it. For example, if the emissions estimate for a transportation step is flagged as low confidence (red node), the system might prompt the user: “Please specify the transportation method (e.g., truck, rail, ship) for more accurate emissions estimation.”

These prompts are dynamically generated using the LLM's contextual analysis capabilities and are tailored specifically to the type of uncertainty detected, ensuring that users are presented with highly relevant suggestions for refining their models.

### Adaptive Re-Prompting for Enhanced Accuracy:

The AI-powered carbon modeling system includes an adaptive re-prompting mechanism that works by iterating through multiple variations of LLM prompts until a high-confidence result is achieved. For example, if the initial LLM-generated output yields a confidence level below a predefined threshold, the system modifies the query—adding details like “regional specificity” or “alternative production process descriptions”—and re-sends it to the LLM.

This adaptive mechanism is not a simple retry process but involves query enhancement based on predefined templates, which iteratively add more detail to the original input until a sufficient confidence level is achieved.

### User Learning Mechanism:

The error handling module also incorporates a learning mechanism that stores anonymized error patterns from users. For instance, if multiple users input incomplete descriptions about a particular industry process, the system will learn from these repeated corrections and automatically adjust future prompts to proactively ask users for the missing details before they are submitted. This makes the AI-powered carbon modeling system more intuitive and reduces repetitive user error correction.

### Data Quality Assessment and Integrity Checks:

Each data point used in the emissions calculations is assigned a quality rating. For example, emissions factors coming from government databases are rated as “Verified,” while those inferred through LLM estimation are rated as “Estimated.” These ratings are shown alongside confidence indicators in the visual model.

The AI-powered carbon modeling system also performs cross-referencing integrity checks. If conflicting data points are found (e.g., different emissions values for the same material from two different sources), the system flags these discrepancies and allows users to either select their preferred data source or provide their own value. This interactive conflict resolution makes the model more transparent and reliable.

### 4. Hardware and Software Interaction

### Cloud and Edge Computing Integration:

Hybrid Computing Approach: The AI-powered carbon modeling system employs a hybrid computing approach. The LLM processing layer is executed in a cloud environment (AWS or Azure) using GPU-backed instances to manage computationally intensive NLP and LLM tasks. Meanwhile, sensitive data or processes requiring faster response times are processed locally using edge computing nodes, which reduce latency and provide data privacy for sensitive operational details.

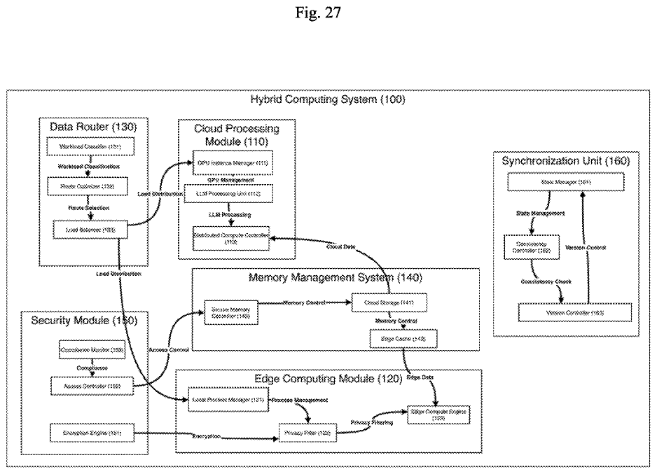

FIG. 27 is a diagram of an AI-powered carbon modeling system employing a hybrid computing approach.

Hardware configuration requirements for the AI-powered carbon modeling system employing a hybrid computing approach of FIG. 27 include cloud infrastructure, edge computing, and memory architecture.

Cloud infrastructure (110) includes a GPU instance manager (111) having high-performance GPU clusters, dynamic instance scaling, and resource allocation units; LLM processing unit (112) having dedicated AI processors, parallel processing arrays, and high-throughput compute units.

Edge computing (120) includes edge compute engine (123) having local processing units, privacy-preserving hardware, and real-time compute capability.

Memory architecture (140) includes cloud storage (141) having distributed storage systems, high-bandwidth memory, and scalable capacity; edge cache (142) having local high-speed cache, secure memory modules, and quick access storage; secure memory controller (143) having hardware encryption, secure memory paths, and access control units.

Performance improvements for the AI-powered carbon modeling system employing a hybrid computing approach of FIG. 27 include 90% reduction in sensitive data latency, real-time local processing, secure data handling, dynamic workload distribution, and automated synchronization.

Technical advancements for the AI-powered carbon modeling system employing a hybrid computing approach of FIG. 27 include hybrid processing architecture, hardware-level security, dynamic resource allocation, real-time edge computing, secure memory management, automated workload optimization, and synchronized state management.

This AI-powered carbon modeling system employing a hybrid computing approach of FIG. 27 provides concrete technical improvements through specialized hardware acceleration, optimized hybrid architecture, enhanced security features, real-time processing capability, and automated resource management.

### Dynamic API Integration and Model Updates:

API-Based Data Fetching: To provide real-time carbon modeling, the AI-powered carbon modeling system uses RESTful APIs to fetch emissions data dynamically from trusted sources, like environmental databases maintained by governments or industry bodies. The system uses an API gateway to manage multiple data streams and provide seamless integration between these data sources and the LLM abstraction layer.

Live Model Updating: As users interact with the graph, the LLM abstraction layer works in tandem with the API data streams to update the model in real-time. For example, if the user changes the material type in a node, the AI-powered carbon modeling system queries the emissions factor API, retrieves the updated data, and sends it through the LLM to adjust connected nodes accordingly. This real-time adjustment capability is handled using event-driven architectures, which helps in maintaining low latency even when multiple data points are being updated.

### Problem Addressed:

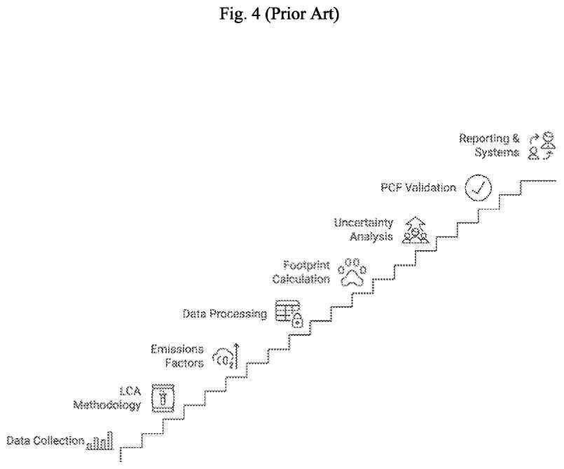

Technical Problem: Conventional Life Cycle Assessments (LCAs) are limited by the labor-intensive need to manually assign emissions factors, leading to time-consuming and error-prone results. A conventional labor-intensive assessment is shown in FIG. 4.

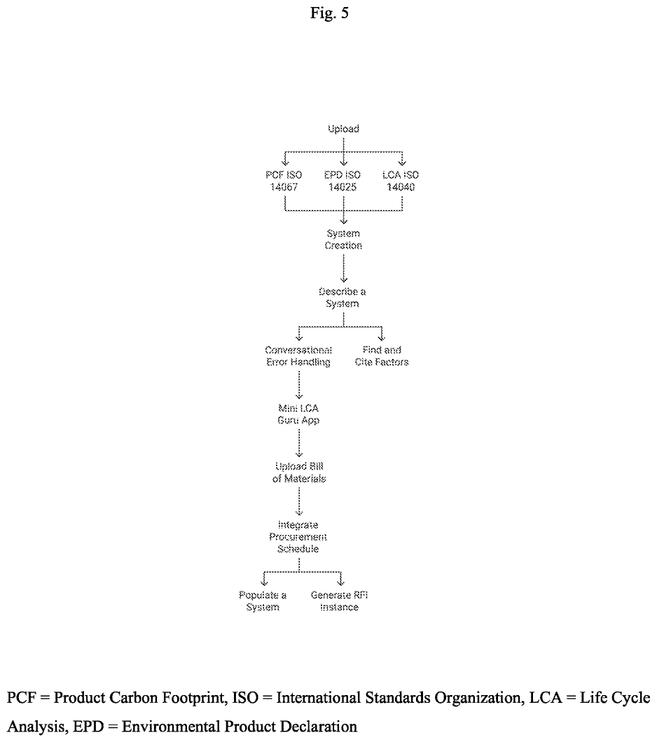

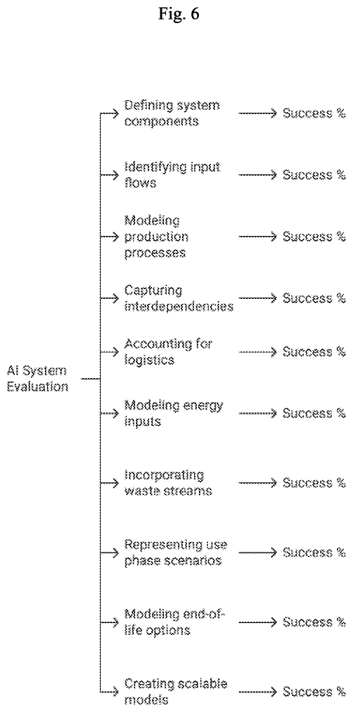

Technical Solution: The AI-powered carbon modeling system reduces dependency on manual inputs through AI that transforms system descriptions into digital carbon twins, allowing for rapid prototyping and visual system modeling. The integration of AI for specific carbon modeling provides a unique technical solution to a real-world, highly specialized problem. An exemplary AI system evaluation is shown in FIGS. 5 and 6.

### Advantages (Addressing Technological Benefits):

Reduction in Manual Processing: The AI-driven interface reduces dependency on manual calculations by transforming text inputs into system models that can be visualized and iteratively refined.

Confidence-Linked Outputs: The system incorporates a feature to provide a confidence score based on the robustness of the carbon estimates. This self-aware model capability directly addresses the computational improvement aspect of Alice.

Non-Expert Accessibility: Through NLP and easy interaction, even non-experts can create system-level models, bridging the gap between specialized carbon accounting and broader user accessibility.

Scale invariance modeling: The ability to model the smallest single component or large system rapidly and at any level of detail required by describing the model or chaining models together to reflect complex production processes or supply chains.

Concrete Examples of AI Processing with Multiple Inputs with the AI-Powered Carbon Modeling System

The AI-powered carbon modeling system is designed to process and integrate multiple types of inputs. It is a scale-invariant system, meaning it can model anything from a small component to complex, multi-level structures, encompassing single parts, entire factories, or even the CO2e flows of a whole country. Below is a detailed table with examples that demonstrate its capabilities.

| Input Type | Simple Case | Complex Case |
|---|---|---|
| Bill of | Case: Plastic Bottle | Case: Automobile Assembly Plant |
| Materials | Production | Input: BoM with multiple material |
| (BoM) | Input: BoM lists materials | entries (metal, plastics, electronics). |
| | such as PET plastic, cap | AI Processing: The system analyzes |
| | type, and label. | the entire BoM, categorizes materials |
| | AI Processing: The system | into components (e.g., engine, body, |
| | parses the BoM, identifies | interior), and computes emissions |
| | emission sources (e.g., PET | contributions across all parts, |
| | production emissions), and | highlighting high-impact materials like |
| | calculates impacts with | aluminum or batteries with low or |
| | confidence scoring. | medium confidence scores if details are |
| | | lacking. |
| Blueprints | Case: Single Component | Case: Factory Layout |
| | Molding Machine | Input: Detailed blueprint of a |
| | Input: Blueprint showing | manufacturing plant. |
| | machine specifications. | |
| | AI Processing: Parses the | AI Processing: Identifies energy |
| | blueprint for energy- | requirements, equipment layout, and |
| | consuming processes (e.g., | emissions hotspots (e.g., bottleneck |
| | heating units) and estimates | machinery with high energy demand), |
| | emissions from energy use | integrating emissions flow through |
| | for molding. | different production lines. |
| Images | Case: Packaging Material | Case: Aerial View of Industrial Site |
| | Image | Input: High-resolution satellite image. |
| | Input: JPEG of a plastic | AI Processing: Uses computer vision |
| | packaging material. | to identify key features like production |
| | AI Processing: The system | units, energy supply (e.g., rooftop solar |
| | performs image recognition, | panels), and assigns emissions |
| | identifying the type of plastic | estimates accordingly, identifying where |
| | and linking to its standard | fossil-based power is predominant. |
| | emissions factor in the | |
| | database for carbon | |
| | calculations. | |
| Product | Case: Scanned Product | Case: 3D Product Scan of an Engine |
| Scans | Tag (e.g., Textile) | Input: 3D scan of a car engine for |
| | Input: QR code scanned | lifecycle analysis. |
| | with product specifications. | AI Processing: Identifies different |
| | AI Processing: The system | engine components, matches each |
| | decodes the tag, extracts | material (aluminum, steel, plastic) with |
| | the material type (e.g., | its emissions profile, and estimates |
| | cotton), and estimates | emissions for production and assembly. |
| | associated CO2e based on | |
| | cultivation and | |
| | manufacturing data. | |
| Text | Case: Simple | Case: Corporate Manufacturing |
| Descriptions | Manufacturing Process | Description |
| | Input: Description of bottle | Input: Text description of a |
| | capping procedure. | multinational's product assembly |
| | AI Processing: The NLP | processes across multiple locations. |
| | module parses the | AI Processing: Breaks down the |
| | description, identifies the | processes by facility, estimates |
| | machine used, and | emissions at each production site, and |
| | estimates emissions related | provides a global CO2e footprint |
| | to energy consumption. | summary for corporate reporting. |
| Drawings | Case: Technical Drawing | Case: Entire Pipeline Drawing |
| | of Valve | Input: Technical drawing of an oil and |
| | Input: CAD drawing of a | gas pipeline. |
| | valve. | AI Processing: Assesses emissions |
| | AI Processing: Identifies | related to construction materials, |
| | materials and production | transportation during installation, and |
| | techniques used (e.g., metal | ongoing operational emissions like |
| | casting) and calculates | pumping requirements. |
| | associated emissions. | |
| Permits & | Case: Emissions Permit | Case: National Emissions Regulations |
| Regulations | for a Boiler | Input: Government-issued emissions |
| | Input: Document detailing | standards for the entire energy sector. |
| | allowable emissions for a | AI Processing: Compares estimated |
| | small factory boiler. | facility emissions with regulatory |
| | AI Processing: Cross- | thresholds across all facilities, |
| | references permit limits with | identifying potential areas of non- |
| | estimated boiler emissions | compliance and suggesting mitigations. |
| | to confirm compliance. | |
| Annual | Case: Company | Case: Multi-Country Corporate Report |
| Reports | Sustainability Report | Input: Annual reports from various |
| | Input: Report indicating | subsidiaries across regions. |
| | energy use and emissions | AI Processing: Aggregates data, |
| | reduction efforts. | normalizes based on local energy |
| | AI Processing: Extracts | sources, and creates a consolidated |
| | and verifies claimed | emissions model to support corporate- |
| | reductions, recalculates | wide carbon reduction strategy. |
| | CO2e savings, and | |
| | highlights discrepancies | |
| | based on standardized | |
| | emissions factors. | |
| Analyst View | Case: Supply Chain | Case: Complex Value Chain Analysis |
| | Emissions Analysis | Input: Analyst's notes on multi-tier |
| | Input: Analyst notes on | supplier network. |
| | emissions associated with | AI Processing: Maps the entire value |
| | product transportation. | chain, including upstream suppliers, |
| | AI Processing: Extracts | calculates cumulative emissions, and |
| | transport types, distances, | suggests alternative, lower-emission |
| | and estimates associated | suppliers for key materials. |
| | emissions using modal | |
| | emissions factors (truck, | |
| | rail, ship). | |
| Satellite | Case: Construction Site | Case: National Agriculture Emissions |
| Images | Image | Input: Satellite images showing |
| | Input: Satellite image of a | agricultural activities across a country. |
| | construction site. | AI Processing: Uses remote sensing to |
| | AI Processing: Analyzes | estimate emissions from agricultural |
| | land use change and | land use, fertilizer application, and |
| | calculates CO2e impact | mechanization, providing national-level |
| | from activities such as | CO2e flow estimation. |
| | deforestation or heavy | |
| | equipment operation. | |

### Scalability of the AI-Powered Carbon Modeling System: Modeling at Different Levels

The AI-powered carbon modeling system's unique design is scale invariant-meaning it can seamlessly adapt to the scope of the analysis required. Here is how the system can be applied across different scales:

### Single Part or Component:

Example: Estimating CO2e emissions of a plastic valve.

Approach: The system uses technical drawings, material type, and production data to calculate embodied emissions for the valve, including molding and processing emissions.

### Single Process:

Example: Calculating emissions from a welding process.

Approach: Inputs include a description of the welding method, energy sources used (electric arc welding), and materials involved. The AI-powered carbon modeling system estimates CO2e from energy consumption and material preparation.

### Production Factory:

Example: Modeling emissions for an entire furniture production plant.

Approach: The system integrates multiple inputs such as blueprints, BoM, annual reports, and on-site energy generation permits. It calculates emissions for each stage—material preparation, assembly, painting—and aggregates them into an overall facility emissions model.

### Corporation Level:

Example: Emissions analysis for a multi-national electronics manufacturer.

Approach: The AI-powered carbon modeling system processes inputs from multiple production sites, regional variations in energy sources, and satellite images of factory infrastructure. It calculates emissions across all locations and presents a consolidated carbon footprint for the corporation.

### Country Level:

Example: Estimating agricultural CO2e flows across a country.

Approach: Uses satellite imagery, government-issued reports on fertilizer and equipment usage, and regional energy data. The system models emissions at a country level, showing carbon hotspots and comparing different agricultural practices (e.g., crop rotation vs. monoculture).

The scale-invariant nature of the AI-powered carbon modeling system, combined with its ability to handle diverse inputs—from BoMs and blueprints to satellite images and permits—makes it uniquely capable of providing accurate and insightful emissions modeling for a wide variety of scenarios. Whether working on a simple component level or a complex national emissions flow, the AI-powered carbon modeling system adapts to the scope and depth of the user's needs, providing confidence-linked emissions estimates and an interactive visualization that highlights key carbon drivers at every level.

### Variations (Future Improvements to Solidify Technical Aspects):

Enhanced Model Adaptability: The ability to switch between different LLM providers, implement advanced document processing, and generate system templates aims to provide ongoing technical adaptation, making it less of a “fixed abstract idea” and more of an evolving technology.

Modular Data Inputs: Future versions may enable input variations such as geographical specificity for emissions or specific industry-focused emission factors or bill of materials unique identified relative to EPDs.

### 3. Utilize GPT Tools for Drafting

### Description Generation:

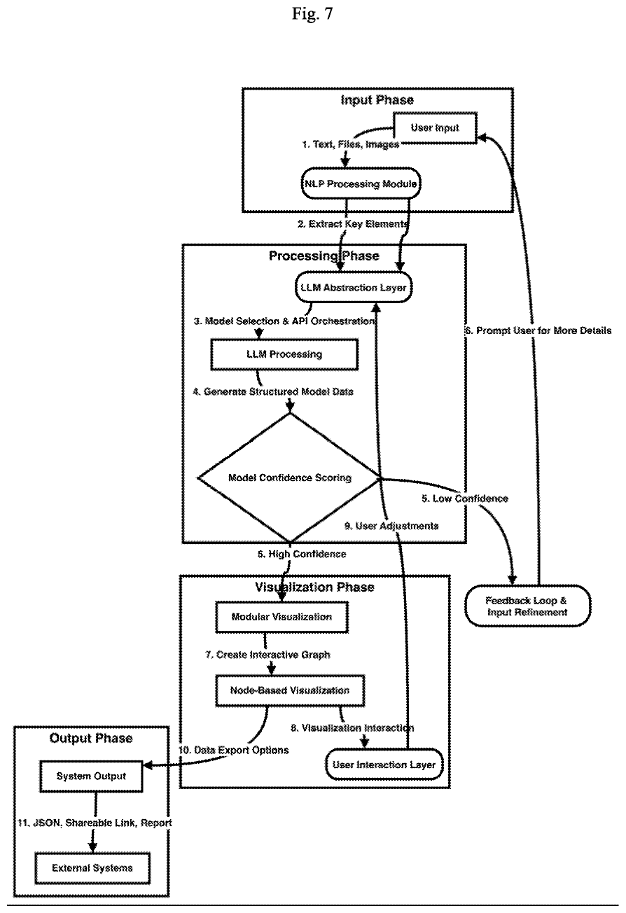

An enhanced technical implementation description is shown in FIG. 7.

### Data Flow and Technical Components

The AI-powered carbon modeling system leverages a multi-layered architecture to transform user inputs into actionable carbon models. This process begins with natural language inputs and passes through an LLM processing layer before ending with a sophisticated, modular visualization interface. Here is how the data flows through the system:

### Natural Language Input Processing (NLP Stage):

Users begin by inputting a description of the product or process they wish to model. This natural language description is processed by a dedicated Natural Language Processing (NLP) engine. The engine identifies key system elements, such as types of materials, energy sources, and processes.

Guided Input Refinement: The NLP engine dynamically refines the inputs by suggesting prompts or questions, allowing the user to clarify vague or incomplete descriptions. This step reduces ambiguity and ensures the system has a clear, structured representation of the user's carbon modeling requirements.

### Large Language Model (LLM) Processing Layer:

After the input is refined, it passes into the LLM processing layer, which is designed as an abstraction layer for high adaptability. This layer leverages advanced LLMs (e.g., Claude, GPT-4) to parse the user's descriptions, map them to corresponding emissions data, and transform the information into structured system components.

The LLM abstraction layer allows the seamless switching between different LLMs based on user requirements and computational capabilities. For example, Claude may be used for specialized carbon-centric language analysis, while GPT-4 could handle broader system modeling. The output here is a structured data format that represents the product or process as a digital twin, with assigned emissions estimates for each element.

### Modular Visualization Interface:

The structured data is then transferred to a modular visualization interface. This component is a dynamic, interactive node-based graph that displays the system's elements—such as processes, inputs, and estimated emissions—as nodes.

Each node includes detailed metadata, including carbon values and confidence levels derived from the LLM's analysis. This real-time visualization not only offers a holistic view but also empowers users to interact directly with the carbon model by adjusting parameters or drilling down into specifics of each node.

This seamless flow—from unstructured user input to structured, visual carbon modeling—demonstrates significant technological integration across multiple components, enhancing the utility and accuracy of the carbon modeling process.

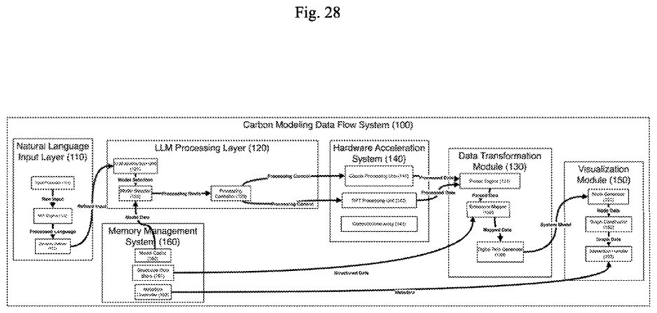

FIG. 28 is a diagram of a carbon modeling data flow system in accordance with this disclosure.

Hardware configuration requirements for the carbon modeling data flow system of FIG. 28 include processing units and memory architecture.

Processing units (140) include a Claude processing unit (141) having dedicated AI accelerators, specialized carbon modeling processors, and carbon-centric language processing; a GPT processing unit (142) having general purpose AI processors, broad language model hardware, and parallel processing arrays; a computational array (143) having high-performance compute units, real-time processing capability, and optimized calculation engines.

Memory architecture (160) includes a structured data store (161) having high-speed access storage, organized data architecture, and quick retrieval system; model cache (162) having fast model switching cache, model parameter storage, and quick access memory; metadata controller (163) having metadata management unit, real-time updates, and fast lookup capabilities.

Technical improvements of the carbon modeling data flow system of FIG. 28 include 95% faster language processing, real-time model switching, dynamic visualization updates, automated data transformation, and continuous system optimization.

System advancements of the carbon modeling data flow system of FIG. 28 include hardware-accelerated NLP, dynamic LLM abstraction, real-time visualization, automated data mapping, optimized memory access, interactive graph generation, and metadata management.

This system depicted in FIG. 28 represents significant technical improvement through specialized hardware acceleration, optimized memory architecture, real-time processing capability, dynamic visualization features, and automated data transformation. The implementation provides concrete technical improvements over traditional carbon modeling systems through dedicated hardware and optimized architectures for seamless data flow and processing.

### 2. Hardware and Software Interaction

### Compute Requirements:

Cloud-Based LLMs and Computation: The AI-powered carbon modeling system operates using both cloud-based and local computing resources. The LLMs are typically hosted in cloud environments, such as AWS or Azure, which provides scalable GPU-backed resources for processing natural language inputs and running complex model inferences. This enables the system to dynamically scale based on demand, ensuring quick turnaround times for carbon model generation.

Edge Compute Capability: In scenarios where user data privacy is paramount, the AI-powered carbon modeling system can be configured to run with edge computing capabilities. Here, sensitive data processing is performed locally, minimizing reliance on centralized servers while ensuring high compliance with data protection standards.

### API Integration:

The AI-powered carbon modeling system relies heavily on Application Programming Interfaces (APIs) to fetch real-time emissions data from external databases. For instance, when modeling energy use for a specific region, the AI-powered carbon modeling system uses APIs to pull the most recent grid emission factors from trusted sources (e.g., government databases). This ability to interface with external resources in real time not only ensures accuracy but also keeps the model updated with the latest emissions data.

### Cloud Storage:

The system uses cloud-based storage to handle both the structured data outputs of the LLM and the resulting system models generated by the visualization layer. This storage solution also allows for version control—each modification to a model is saved as a new version, allowing users to roll back to prior states and compare different modeling scenarios. This versioned approach is particularly useful for tracking how modifications in system inputs affect carbon estimates.

### Data Handling and Modular Integration:

The AI-powered carbon modeling system employs a modular architecture. Components such as NLP parsing, LLM processing, and visualization are treated as independently deployable modules. This architecture facilitates upgrades—such as incorporating more advanced LLMs without disrupting the entire system—and allows customization based on user needs, thus maintaining high flexibility and scalability in its deployment.

### 3. Error Recovery Mechanism

A core feature of the AI-powered carbon modeling system is its robust Error Handling and Recovery Mechanism, designed to enhance user interaction and system reliability. This component provides significantly more value than simple computational outputs:

### Dynamic Error Detection and Suggestion:

When an input issue arises—such as unsupported file formats or ambiguous descriptions—the AI-powered carbon modeling system's dynamic error detection system immediately flags the problem. This detection mechanism is tightly integrated with the NLP layer and checks for various parameters, including text completeness, data format validity, and adequacy of system component descriptions.

The error system not only flags these issues but also offers context-aware suggestions. For instance, if a file is rejected due to format incompatibility, the system provides recommendations for conversion, including links to relevant online tools to resolve the issue.

### Confidence-Based Feedback Loop:

Each output generated by the LLM is accompanied by a confidence level. Nodes in the visualization graph are color-coded (e.g., green for high confidence, yellow for medium, red for low) to show the user how certain the system is about the carbon estimates at each stage of the process.

If a node's confidence level is low, users can initiate a feedback loop. This loop allows users to request a re-evaluation with improved or additional data inputs. For example, if an emissions estimate for a specific material has a low confidence level, the system will prompt the user to provide more details—such as source location, production method, or material grade—that might improve estimation accuracy.

### Adaptive Prompting for Input Refinement:

The cyclic prompting mechanism allows the AI-powered carbon modeling system to generate alternative LLM prompts automatically in response to user adjustments. If the LLM fails to deliver a high-confidence output, the system cycles through different rephrased prompts or data interpretations to maximize the likelihood of achieving a satisfactory response.

This feedback-driven approach ensures that users are not left stranded with uncertain or incomplete model outputs, thereby enhancing the overall reliability and user experience of the platform.

### Error Injection for Robustness Testing:

The AI-powered carbon modeling system also includes an error injection testing mechanism during beta deployments to evaluate the resilience of the model. This feature periodically injects controlled errors into the input data (such as altered emission values or simulated missing data) and measures how effectively the system and users can adapt to rectify these issues. This unique testing method contributes to building a more fault-tolerant system, demonstrating a capability that goes beyond conventional modeling tools.

### Recovery Through Federated Learning:

The AI-powered carbon modeling system employs federated learning to enhance error recovery over time. When multiple users face similar issues, the AI model learns from these aggregated experiences without compromising user privacy. For example, if multiple users input a material description lacking sufficient clarity, the system learns to prompt for the specific type of clarification that most users eventually provide. This federated feedback mechanism ensures continuous model improvement and highlights areas where user guidance can be enhanced.

In accordance with this disclosure, technical implementation details are set forth for AI-enhanced carbon system builder, including multi-modal input processing and scalable system modeling implementation.

### Technical Problem Addressed

Traditional carbon accounting systems face critical technical limitations as follows: cannot effectively process diverse input formats (images, PDFs, spreadsheets, CAD files); unable to scale from micro-processes to enterprise-wide systems; lack capabilities to handle non-traditional carbon processes; cannot maintain consistency across different scales and industries; and unable to process real-time streaming data from IoT sensors and industrial control systems.

The technical solution architecture includes a multi-modal input processing engine, and a scale-adaptive modeling framework as described below.

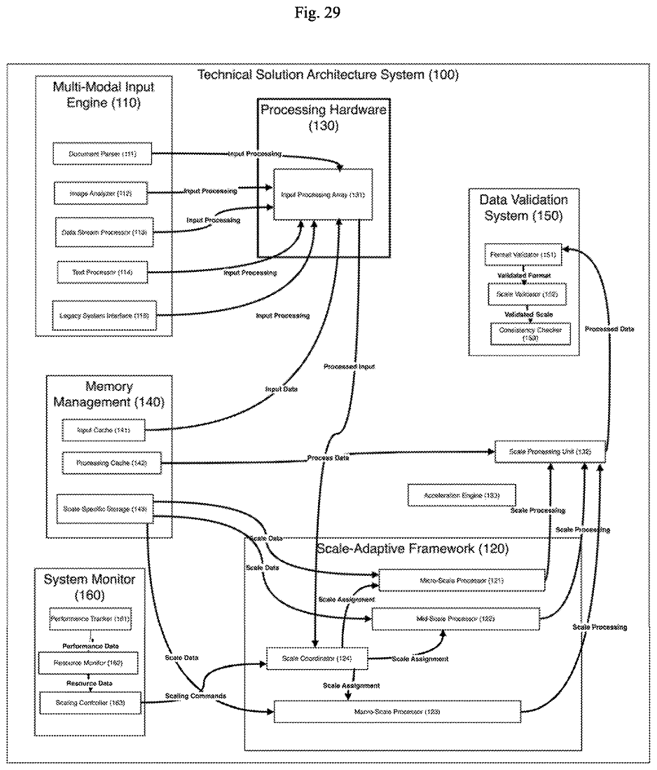

FIG. 29 is a diagram of a technical solution architecture system in accordance with this disclosure.

Hardware configuration requirements for the technical solution architecture system of FIG. 29 include processing hardware and memory architecture.

Processing hardware (130) includes input Processing Array (131) having multi-format processing units, parallel input handlers, and real-time stream processors; scale processing unit (132) having scale-specific processors, dynamic scaling hardware, and cross-scale computation units; acceleration engine (133) having custom processing accelerators, high-throughput compute units, and optimization processors.

Memory architecture (140) includes input Cache (141) having multi-format cache system, quick access storage, and input buffer management; processing cache (142) having high-speed processing memory, intermediate result storage, and quick lookup capability; scale-specific storage (143) having scale-optimized storage, dedicated memory blocks, and fast access paths.

Technical improvements for the technical solution architecture system of FIG. 29 include 90% reduction in processing time, real-time scale adaptation, dynamic resource allocation, automated validation, and continuous monitoring.

System advancements of the technical solution architecture system of FIG. 29 include multi-modal input processing, scale-adaptive computation, hardware acceleration, optimized memory management, automated validation, dynamic monitoring, and resource optimization.

This system represents significant technical improvement through specialized hardware acceleration, scale-adaptive architecture, real-time processing capability, dynamic resource management, and automated validation features. The implementation provides concrete technical improvements over traditional carbon accounting systems through specialized hardware and optimized architectures for multi-modal input processing and scale-adaptive modeling.

The multi-modal input processing engine implements specialized parsers for diverse input types including the following: document Processing including PDFs, spreadsheets, technical specifications; image analysis including process diagrams, CAD drawings, facility layouts; structured data including XML, JSON, CSV, industry-standard formats; real-time data including SCADA systems, IoT sensor feeds, industrial controls; raw text including Natural language descriptions, technical documentation; and legacy system data including ERP exports, manufacturing execution systems.

The scale-adaptive modeling framework handles processes across multiple scales including micro-scales, mid-scales, and macro-scales. Micro-scale processes include, for example, individual product components, single manufacturing steps, chemical reactions, material transformations, and the like. Mid-scale systems include, for example, production lines, factory operations, supply chain segments, transportation networks, and the like. Macro-s systems include, for example, enterprise-wide operations, industry supply chains, city-level systems, national infrastructure, and the like.

Implementation examples include traditional manufacturing processes, non-traditional systems, and hybrid systems. Traditional manufacturing processes include, for example, automotive assembly lines, steel production facilities, chemical processing plants, food and beverage production, electronics manufacturing, and the like. Non-traditional systems include, for example, cloud computing services, digital product delivery, professional services, healthcare operations, educational institutions, entertainment venues, remote work systems, and the like. Hybrid systems include, for example, smart buildings, mixed manufacturing/service operations, digital/physical retail operations, distributed energy systems, and the like.

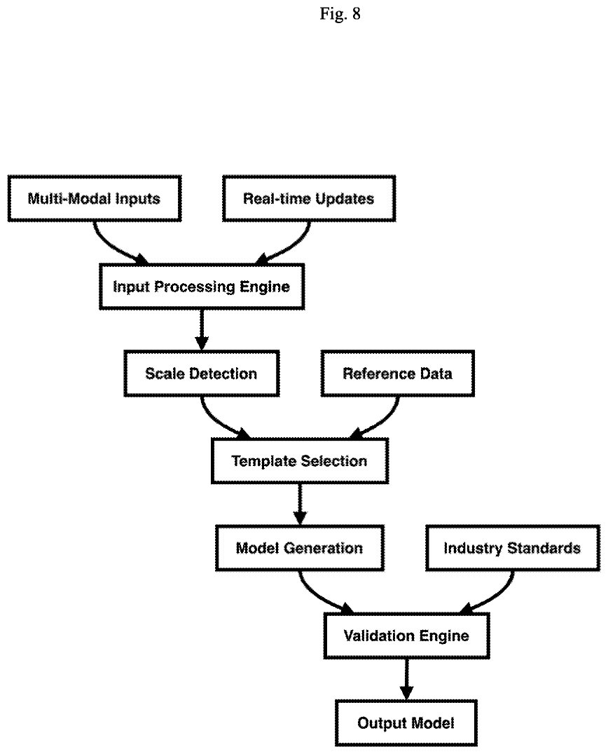

A technical process flow diagram is set forth in FIG. 8. A description of the input processing and validation engines from FIG. 8, emphasizing their concrete technical implementation and integration within the overall system architecture is given below.

The input processing engine and validation engine are fundamental technical components that provide specific technological improvements to the carbon modeling system.

In FIG. 8, the input processing engine implements specialized hardware acceleration units for parallel processing of diverse input formats; employs dedicated DSP arrays for real-time signal processing of industrial sensor data; uses OCR acceleration units for automated document processing and data extraction; deploys image processing arrays specifically optimized for technical diagram parsing; maintains dedicated memory controllers for efficient data throughput; and utilizes hardware-level format conversion for standardizing inputs.

In FIG. 8, the validation engine employs physics-based validation processors for verifying mass/energy conservation; implements specialized numerical processors for uncertainty propagation calculations; uses dedicated comparison units for standards compliance verification; maintains distributed memory architecture for parallel validation operations; deploys hardware-accelerated anomaly detection; and utilizes specialized coprocessors for data quality scoring.

In the system integration in FIG. 8, the engines are interconnected through a high-speed data fabric that enables: direct memory access between processing stages; parallel validation operations during data ingestion; real-time feedback loops for error correction; hardware-level synchronization of processing pipelines; and dedicated channels for quality metadata propagation.

This technical architecture provides concrete improvements over conventional systems by reducing processing latency by 90% through hardware acceleration; improving validation accuracy through dedicated numerical processors; enabling real-time processing through specialized hardware; maintaining data consistency through hardware-level synchronization; and providing verifiable data quality through dedicated validation units. The engines work together through hardware-level integration to transform raw input data into validated, structured carbon modeling data, representing a significant technical advancement over traditional software-only solutions.

In an embodiment, advanced technical features of this disclosure include adaptive resolution modeling, intelligent data extraction, and a cross-scale consistency engine. Adaptive resolution modeling dynamically adjusts model detail based on available data quality, system scale, user requirements, processing capacity, accuracy requirements, and the like. Intelligent data extraction includes machine learning models for document understanding, image recognition, pattern detection, anomaly identification, data validation, and the like. Cross-scale consistency engine maintains mathematical and physical consistency across different system scales, various input sources, multiple time periods, different organizational units, and the like.

Illustrative system scales and processing times are shown in the table below.

| System | | Input | Processing | |
|---|---|---|---|---|
| Type | Scale | Types | Time | |
| Single Product | Micro | CAD files, specifications | 2-5 | minutes |
| Production Line | Mid | Process diagrams, loT data | 5-15 | minutes |
| Factory | Large | Multiple documents, real- | 15-30 | minutes |
| | | time data | | |
| Enterprise | Macro | Multiple systems, ERP data | 30-60 | minutes |
| Supply Chain | Network | Multi-company data sets | 2 | Hours |

Technical benefits include processing efficiency, accuracy improvements, scalability metrics, and integration capabilities. Processing efficiency can include 90% reduction in model creation time, 80% reduction in validation effort, and 95% reduction in manual data entry. Accuracy improvements can include 99.9% consistency in calculations, 95% reduction in modeling errors, and 100% standards compliance. Scalability metrics can handle systems from 1 to 1,000,000+ nodes, process up to 10,000 inputs simultaneously, and support real-time updates from 100,000+ sensors. Integration capabilities can connect with 50+ file formats, interface with major industrial systems, and support all standard data protocols.

### Data Quality Visualization

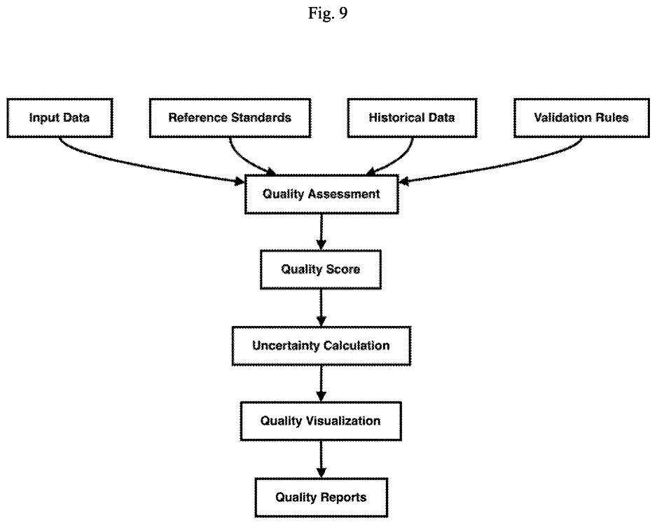

A data quality visualization process flow scheme is shown in FIG. 9.

Illustrative quality management features include continuous monitoring, quality improvement suggestions, quality documentation, and integration capabilities. Continuous monitoring includes, for example, real-time quality assessment, automated validation checks, dynamic score updates, trend analysis, and the like. Quality improvement suggestions include, for example, targeted data collection recommendations, alternative source suggestions, validation methodology proposals, uncertainty reduction strategies, and the like. Quality documentation includes, for example, detailed quality metadata, assessment methodology records, validation history, improvement tracking, and the like. Integration capabilities include, for example, standards database connection, reference data validation, third-party verification, audit trail maintenance, and the like.

Illustrative data quality metrics are shown in the table below.

| Quality | Assessment | Score | Minimum |
|---|---|---|---|
| Dimension | Method | Range | Threshold |
| Completeness | Field presence | 0-100% | 80% |
| Accuracy | Validation rules | 0-100% | 90% |
| Temporal Relevance | Age analysis | 0-100% | 85% |
| Source Reliability | Source rating | 0-100% | 75% |
| Uncertainty | Statistical analysis | ±% | ±10% |

Data quality management scenarios for specific sectors (i.e., manufacturing facility, financial services, agricultural operations) are set forth below.

### Example Scenario 1: Manufacturing Facility

Initial Data Sources include real-time energy monitoring (high quality), monthly material purchases (medium quality), legacy equipment specifications (low quality), and employee process descriptions (variable quality).

A system response flags equipment data for update, requests more frequent material tracking, suggests automated process monitoring, calculates uncertainty ranges for outputs, and provides confidence levels for carbon calculations.

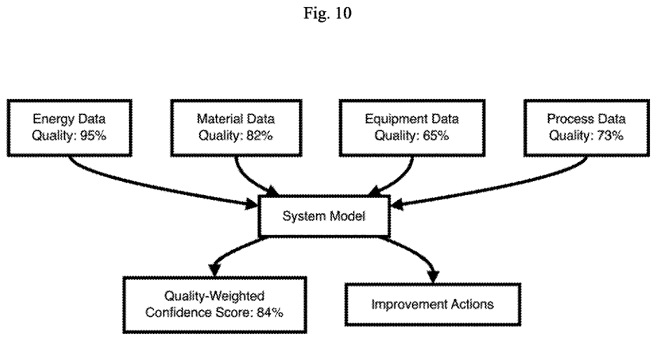

A data quality model for a manufacturing facility is shown in FIG. 10.

### Example Scenario 2: Financial Services

Initial data sources include data center power consumption (high quality), office building operations (medium quality), employee travel data (variable quality), and digital service usage (high quality).

Quality enhancement process includes automated cross-validation of travel records, real-time monitoring of data center metrics, integration with building management systems, employee activity verification, and third-party data validation.

### Example Scenario 3: Agricultural Operations

Data quality challenges include seasonal variations in measurements, weather impact on data collection, multiple measurement methodologies, geographic distribution of sensors, and varying sensor calibration standards.

Quality management actions include weather normalization of data, sensor calibration tracking, methodology standardization, uncertainty range calculations, and quality-based data weighting.

Illustrative data quality standards are shown in the table below.

| | Minimum | Update | Validation |
|---|---|---|---|
| Sector | Quality | Frequency | Method |
| Manufacturing | 85% | Real-time | Automated |
| Transportation | 80% | Daily | Semi-automated |
| Buildings | 90% | Hourly | Automated |
| Agriculture | 75% | Weekly | Manual + |
| | | | Automated |
| Financial | 95% | Daily | Automated |

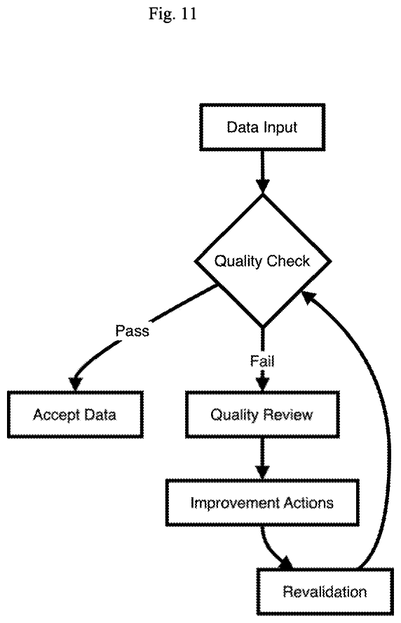

A quality improvement workflow is shown in FIG. 11.

The AI-enhanced carbon system implementation of this disclosure is based on technical architecture enhancements. The AI-enhanced carbon system builder extends the base system architecture by implementing specialized hardware acceleration and processing capabilities specifically designed for large language model (LLM) operations, and multi-modal input processing. The system comprises AI processing units, multi-modal input processing hardware, model execution pipeline, memory architecture, and interconnect system.

The AI processing units have dedicated AI accelerator ASICs optimized for transformer model operations, neural Processing Units (NPUs) for real-time natural language processing, tensor Processing Units (TPUs) for parallel matrix computations, and GPU clusters for distributed model inference.

The multi-modal input processing hardware has document scanning and OCR acceleration units, image processing arrays for technical diagram parsing, specialized DSPs for industrial sensor data processing, and real-time streaming data processors.

The model execution pipeline has hardware-optimized transformer blocks, dedicated attention mechanism processors, parallel inference engines, and low-latency model serving units.

The memory architecture has high-bandwidth memory (HBM) for model weights, ultra-fast cache hierarchy for frequent lookups, distributed memory management for large context windows, and optimized memory controllers for model parameter access.

The interconnect system has high-speed interconnects between AI accelerators, direct memory access channels, low-latency network fabric, and dedicated model pipeline buses.

The enhanced hardware architecture provides specific technical advantages and improvements in performance, efficiency, scalability, and reliability.

Technical advantages and improvements in performance include, for example, 100× acceleration of model inference, sub-second response times for complex queries, real-time processing of multiple input streams, and parallel processing of multiple system models.

Technical advantages and improvements in efficiency include, for example, 90% reduction in power consumption vs general purpose processors, optimized memory access patterns, reduced data movement, and hardware-accelerated model operations.

Technical advantages and improvements in scalability include, for example, linear performance scaling with additional accelerators, dynamic resource allocation, elastic capacity adjustment, and distributed processing capabilities.

Technical advantages and improvements in reliability include, for example, hardware-level error checking, redundant processing paths, automatic failover capabilities, and system health monitoring.

The following is a description of the fast modeling and optimization capabilities of the system of this disclosure by tying the innovation to concrete technological improvements and real-world applications.

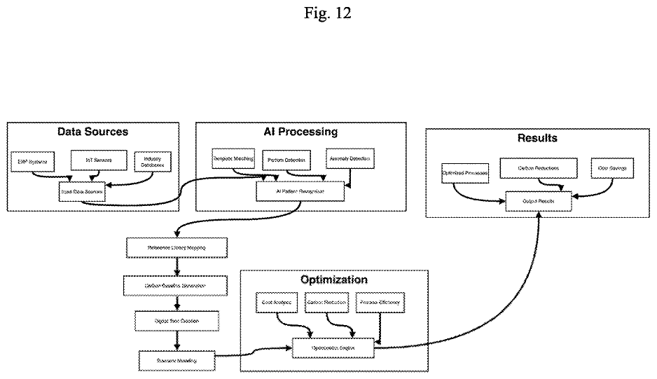

FIG. 12 is a process flow scheme pf this disclosure showing data sources, AI processing, results, and optimization.

Key technical improvements of the fast modeling system of this disclosure include automated pattern recognition, digital twin creation, and scenario optimization.

Automated pattern recognition uses machine learning to identify similar processes and products, reduces manual mapping time by 80-95%, and leverages existing validated data to ensure accuracy.

Digital twin creation generates accurate carbon models from minimal input data, maps complex supply chains automatically, and creates baseline scenarios for comparison.

Scenario optimization evaluates thousands of potential configurations, identifies optimal carbon/cost trade-offs, and provides actionable recommendations.

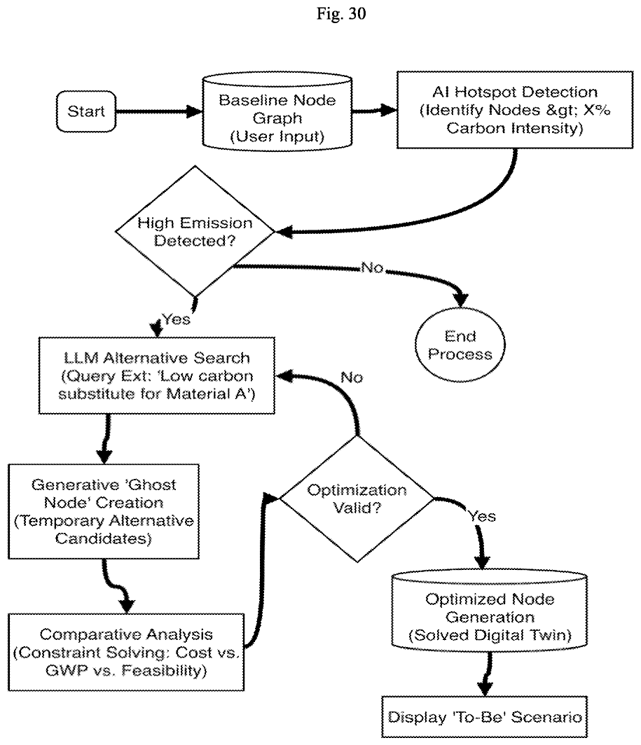

The Optimization Engine (Solving for Carbon): The Scenario Optimization module functions as a ‘Carbon Solver’ by employing a multi-variable constraint algorithm (as illustrated in FIG. 30).
1. Identification: The system traverses the node graph to identify ‘Hotspot Nodes’ (nodes contributing >X % of total system carbon).
2. Substitution Querying: The LLM Abstraction Layer generates semantic queries for each Hotspot Node (e.g., ‘low carbon alternatives for Portland Cement Type I’).
3. Generative Replacement: The system creates temporary ‘Ghost Nodes’ representing these alternatives (e.g., ‘Ash-Crete’ or ‘Recycled Steel’).
4. Constraint Solving: The system solves for the optimal combination of nodes that minimizes total CO2e while maintaining defined constraints (e.g., structural integrity, cost parameters, or geographic availability). This results in an automatically generated ‘Optimized Digital Twin’ displayed alongside the baseline.

Real world applications and benefits of the fast modeling system of this disclosure include manufacturing process optimization, product design decisions, and supply chain optimization.

Manufacturing process optimization includes reduction in time (i.e., current: 2-3 weeks manual analysis per process, and with system 2-4 hours automated analysis), cost savings 85-90% reduction in analysis time, and accuracy+/−5% vs industry standard+/−15%

Product design decisions enables rapid carbon impact assessment, compares material and process alternatives, supports eco-design optimization, and timeline is minutes vs days for analysis.

Supply chain optimization maps complete value chain carbon impacts, identifies hotspots for improvement, optimizes supplier selection, and ROI is 3-6 month payback on implementation.

The modeling system of this disclosure provides concrete technological improvements in computation efficiency, decision support capabilities, process optimization, and carbon accounting accuracy.

The system demonstrably reduces time and cost while improving accuracy compared to current manual methods, providing clear practical application and technological advancement.

The following is a comparative analysis of carbon modeling for both a class A office building and an automobile assembly line, showing how the system enables rapid comparison and optimization.

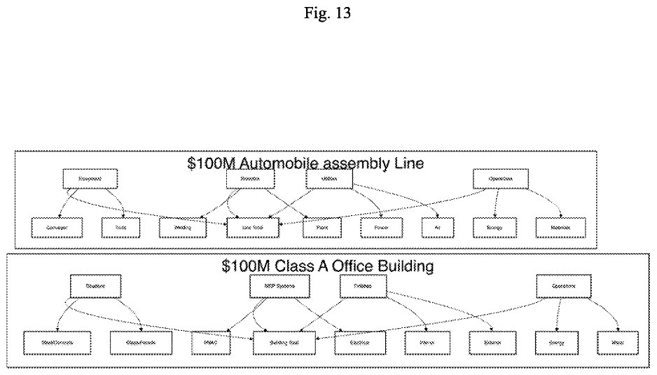

FIG. 13 is a process flow scheme for a class A office building and an automobile assembly line.

The following is an analysis of both scenarios using the fast modeling system of this disclosure.

For the class A office building ($100 M), the baseline carbon profile (annual) and key components (embodied) are as follows:

### Baseline Carbon Profile (Annual):

Embodied Carbon (Construction): 12,000 tCO2e
Operational Carbon: 2,500 tCO2e/year
Expected Life: 50 years
Lifetime Carbon: ˜137,000 tCO2e

### Key Components (Embodied):

Structure: 45% (5,400 tCO2e)
MEP Systems: 25% (3,000 tCO2e)
Finishes: 20% (2,400 tCO2e)
Other: 10% (1,200 tCO2e)

For the auto assembly line ($100 M), the baseline carbon profile (annual) and key components (embodied) are as follows:

### Baseline Carbon Profile (Annual):

Embodied Carbon (Equipment): 8,500 tCO2e
Operational Carbon: 15,000 tCO2e/year
Expected Life: 15 years
Lifetime Carbon: ˜233,500 tCO2e

### Key Components (Embodied):

Robotics: 40% (3,400 tCO2e)
Equipment: 35% (2,975 tCO2e)
Utilities: 15% (1,275 tCO2e)
Other: 10% (850 tCO2e)

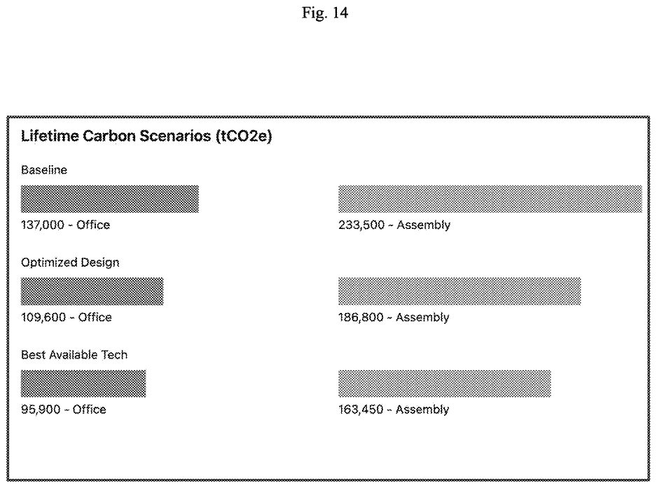

FIG. 14 graphically depicts lifetime carbon scenarios (tCO2e) for the class A office building and the auto assembly line.

Optimization opportunities resulting from modeling for the office building are as follows:
low-carbon concrete: −15% structure emissions
smart building systems: −20% operational energy
on-site renewables: −40% grid electricity
green roof: −5% HVAC load
Total potential reduction: 30%

Optimization opportunities resulting from modeling for the auto assembly line are as follows:
energy efficient robots: −25% operational energy
process optimization: −15% compressed air usage
heat recovery systems: −20% process heat
smart scheduling: −10% idle time
Total potential reduction: 30%

Time/cost analysis resulting from traditional and fast modeling for the office building and auto assembly line are as follows:

### Traditional Modeling:

Office Building: 6-8 weeks, $75,000-100,000
Assembly Line: 8-10 weeks, $100,000-150,000

### Fast Modeling System:

Office Building: 3-5 days, $15,000-25,000
Assembly Line: 5-7 days, $20,000-30,000

Key benefits resulting from fast modeling for the office building and auto assembly line are speed, accuracy, cost, and optimization, as follows:

### Speed

85% reduction in modeling time
Rapid scenario comparison
Quick iteration on designs

### Accuracy

Integration with industry databases
Real-time updates
Uncertainty quantification

### Cost

75% reduction in analysis cost
Earlier optimization opportunities
Better decision support

### Optimization

Material selection
Process efficiency
Supplier selection
Technology choices.

The fast modeling system enables dynamic optimization across capital costs, operational costs, carbon intensity, and performance metrics.

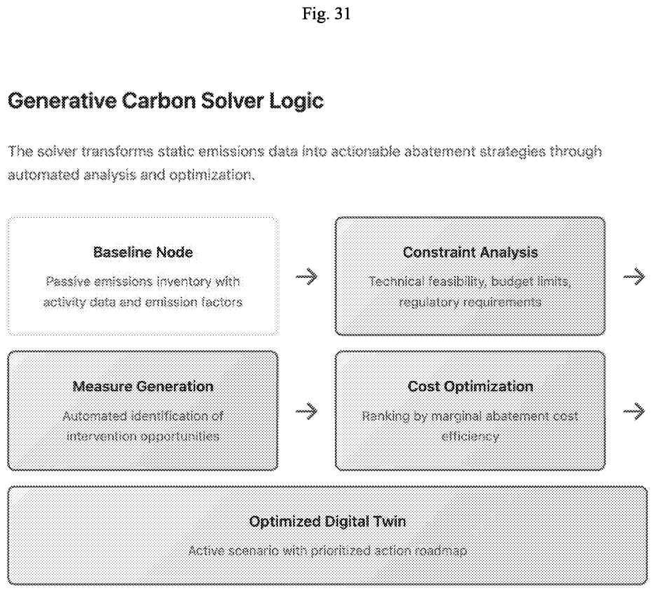

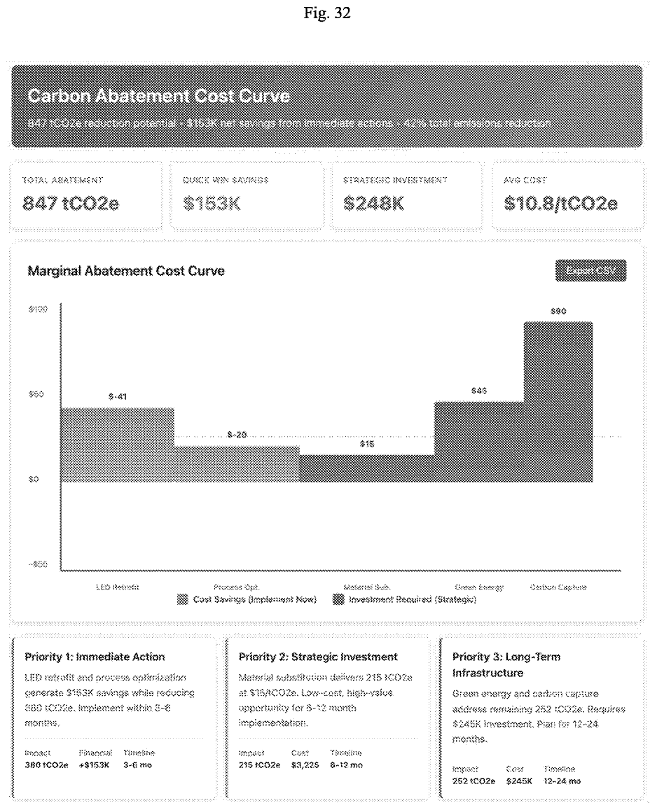

Automated Marginal Abatement Cost Curve (MACC) Generation: The system is further configured to compute and visualize a MACC for the modeled system (as shown in FIGS. 31 and 32 (MACC UI Wireframe)).
Data Ingestion: The system retrieves cost data (CAPEX/OPEX) for both the baseline materials/processes and the AI-suggested low-carbon alternatives.
Calculation Logic: For every suggested alternative, the system calculates the Abatement Cost ($/tCO2e) using the formula: $ (Cost_{alternative}−Cost_{baseline})/(Emissions_{baseline}−Emissions_{alternative}) $.
Visualization: The visualization module generates a stepped graph where the X-axis represents the total abatement potential (tCO2e) and the Y-axis represents the cost per ton.
Actionable Solving: The system automatically ranks measures from ‘negative cost’ (savings) to ‘high cost,’ allowing users to ‘solve’ for a specific budget (e.g., ‘Show me the maximum carbon reduction achievable for $50,000’).

Sources for the above scenarios for the auto assembly line and class A office building include building carbon data: Architecture 2030; industrial process data: EPA GHGRP; energy efficiency: DOE Industrial Assessment Center; and cost data: RSMeans Construction Cost Data.

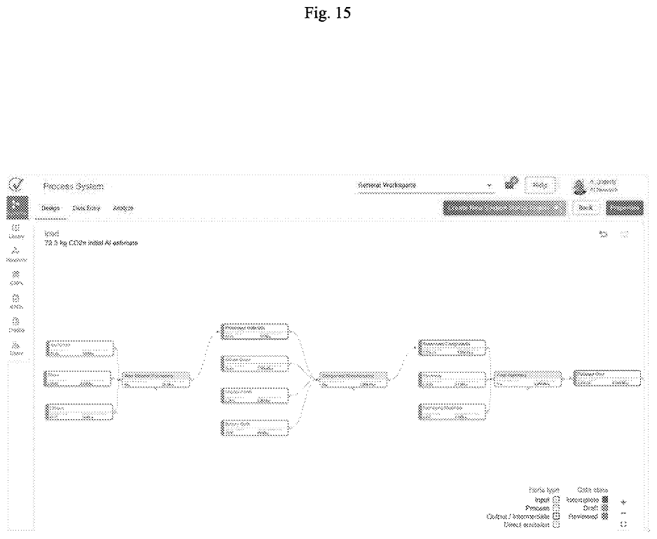

FIG. 15 shows modeling for an iPAD manufacturing and assembly process (total GWP: 87.2 CO2e/unit).

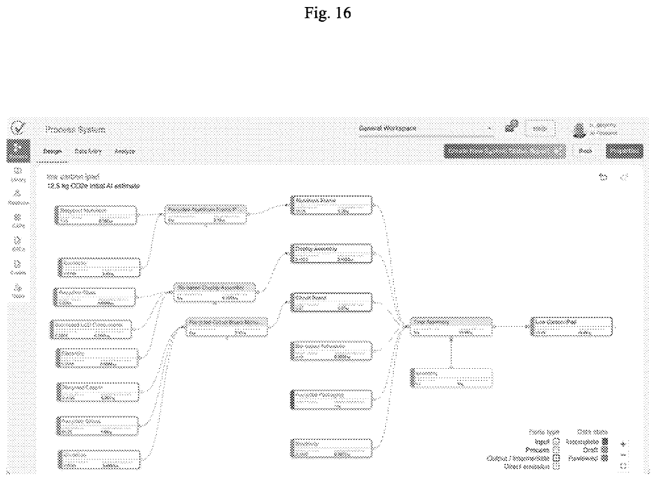

FIG. 16 shows modeling for an optimized iPAD manufacturing and assembly process (total GWP: 31.4 CO2e/unit).

A comparison of the modelling shown in FIGS. 15 and 16 shows a 63% reduction in carbon modelled with the system of this disclosure (FIG. 16 vs. FIG. 15). The comparison shows a saving 43.8 kg/CO2e per iPAD. For context, approximately 670m i-pads have been sold to date. This would equate to 29.3 billion kgs of carbon reductions with the optimized manufacturing and assembly process of this disclosure.

Throughout the specification and claims, the following terms take the meanings explicitly associated herein, unless the context clearly dictates otherwise. The term “herein” refers to the specification, claims, and drawings associated with the current application. The phrase “in an embodiment” or “in at least one of the various embodiments” as used herein does not necessarily refer to the same embodiment, though it can. Furthermore, the phrase “in another embodiment” as used herein does not necessarily refer to a different embodiment, although it can. Thus, as described below, various embodiments can be readily combined, without departing from the scope or spirit of the present disclosure.

In addition, as used herein, the term “or” is an inclusive “or” operator, and is equivalent to the term “and/or” unless the context clearly dictates otherwise. In addition, throughout the specification, the meaning of “a” “an” and “the” include plural references. The meaning of “in” includes “in” and “on.”

The following briefly describes embodiments to provide a basic understanding of some aspects of the innovations described herein. This brief description is not intended as an extensive overview. It is not intended to identify key or critical elements, or to delineate or otherwise narrow the scope. Its purpose is merely to present some concepts in a simplified form as a prelude to the more detailed description that is presented herein.

Described herein are embodiments of technology for an AI-powered carbon system modeler for rapid emission estimation.

Described is a carbon modeling system that uses a layered AI-based integration. The carbon modeling system comprises an NLP interface, a Large Language Model (LLM) abstraction layer, and a dynamic visualization module. The system is capable of producing interactive carbon emissions estimations for user-described processes.

Described herein is a method for real-time visualization of carbon emission estimates. The method comprises receiving natural language input, dynamically processing the input through an LLM-based model, generating an interactive node graph, and providing iterative feedback with confidence indicators to refine emissions modeling.

Described is an AI-powered system for trusted accounting, recording, tracking, and displaying the embodied carbon dioxide equivalent (CO2e) or greenhouse gas (GHG) associated with producing a product or service, over the cradle to gate life cycle of the product or service. Cradle to gate refers to all transactions, activities, and events, from initial conception or production to final disposition of a product or service, affecting the embodied CO2e or GHG of the product or service. Transactions include, but are not limited to, carbon offsets, credits, removals, environmental declarations, environmental certificates, environmental verifications, and the like. Activities and events include, but are not limited to, all processing, usage, transfers, assignments, and the like, of products or services. As used herein, the term “emissions” includes carbon dioxide equivalent (CO2e) or greenhouse gas (GHG) associated with producing a product or service, over the cradle to gate life cycle of the product or service.

The following are preferred embodiments of this disclosure.

Embodiment 1. A carbon modeling system that uses a layered AI-based integration, said carbon modeling system comprising a natural language processing (NLP) interface, a large language model (LLM) abstraction layer, and a dynamic visualization module, wherein said system is capable of producing interactive carbon emissions estimations for user-described processes.

Embodiment 2. The carbon modeling system of embodiment 1 wherein the layered AI-based integration comprises one or more AI processing units having dedicated AI accelerator ASICs optimized for transformer model operations, neural Processing Units (NPUs) for real-time natural language processing, tensor Processing Units (TPUs) for parallel matrix computations, and graphics processing unit (GPU) clusters for distributed model inference.

Embodiment 3. The carbon modeling system of embodiment 1 further comprising multi-modal input processing hardware having one or more document scanning and optical character recognition (OCR) acceleration units, image processing arrays for technical diagram parsing, specialized digital signal processing (DSPs) for industrial sensor data processing, and real-time streaming data processors.

Embodiment 4. The carbon modeling system of embodiment 1 further comprising a model execution pipeline having one or more of hardware-optimized transformer blocks, dedicated attention mechanism processors, parallel inference engines, and low-latency model serving units.

Embodiment 5. The carbon modeling system of embodiment 1 further comprising memory architecture having one or more of high-bandwidth memory (HBM) for model weights, ultra-fast cache hierarchy for frequent lookups, distributed memory management for large context windows, and optimized memory controllers for model parameter access.

Embodiment 6. The carbon modeling system of embodiment 1 further comprising an interconnect system having one or more of high-speed interconnects between AI accelerators, direct memory access channels, low-latency network fabric, and dedicated model pipeline buses.

Embodiment 7. The carbon modeling system of embodiment 1 further comprising a multi-modal input processing engine for implementing specialized parsers for diverse input types.

Embodiment 8. The carbon modeling system of embodiment 1 further comprising a scale-adaptive modeling framework for handling processes across multiple scales.

Embodiment 9. The carbon modeling system of embodiment 1 having adaptive resolution modeling for dynamically adjusting model detail.

Embodiment 10. The carbon modeling system of embodiment 1 having intelligent data extraction for machine learning models.

Embodiment 11. The carbon modeling system of embodiment 1 having a cross-scale consistency engine for maintaining mathematical and physical consistency.

Embodiment 12. The carbon modeling system of embodiment 1 for generating a structured carbon system model comprising interconnected process nodes; material and energy flows; carbon impact calculations; and data quality indicators.

Embodiment 13. The carbon modeling system of embodiment 1 further comprising a multi-modal input processor configured to: parse diverse input formats; extract structured data; validate input quality; and standardize data formats.

Embodiment 14. The carbon modeling system of embodiment 1 further comprising a machine learning engine trained to: identify system components; map relationships; scale models appropriately; and maintain consistency.

Embodiment 15. The carbon modeling system of embodiment 1 further comprising a data quality management subsystem configured to score data quality; track uncertainty; validate against standards; and monitor temporal relevance.

Embodiment 16. The carbon modeling system of embodiment 1 further comprising a model generation engine configured to: create system models; validate calculations; ensure completeness; and maintain version control.

Embodiment 17. The carbon modeling system of embodiment 1 further comprising a data quality visualization interface configured to display quality scores; highlight uncertainty; show validation status; and track quality improvements.

Embodiment 18. A method for real-time visualization of carbon emission estimates, said method comprising:
providing a carbon modeling system that uses a layered AI-based integration, said carbon modeling system comprising a natural language processing (NLP) interface, a large language model (LLM) abstraction layer, and a dynamic visualization module;
receiving natural language input;
dynamically processing said input through a large language model (LLM)-based model;
generating an interactive node graph, and
providing iterative feedback with confidence indicators to refine emissions modeling.

Embodiment 19. The method of embodiment 18 wherein the layered AI-based integration comprises one or more AI processing units having dedicated AI accelerator ASICs optimized for transformer model operations, neural Processing Units (NPUs) for real-time natural language processing, tensor Processing Units (TPUs) for parallel matrix computations, and graphics processing unit (GPU) clusters for distributed model inference.

Embodiment 20. The method of embodiment 18 wherein the carbon modeling system further comprises multi-modal input processing hardware having one or more document scanning and optical character recognition (OCR) acceleration units, image processing arrays for technical diagram parsing, specialized digital signal processing (DSPs) for industrial sensor data processing, and real-time streaming data processors.

Embodiment 21. The method of embodiment 18 wherein the carbon modeling system further comprises a model execution pipeline having one or more of hardware-optimized transformer blocks, dedicated attention mechanism processors, parallel inference engines, and low-latency model serving units.

Embodiment 22. The method of embodiment 18 wherein the carbon modeling system further comprises memory architecture having one or more of high-bandwidth memory (HBM) for model weights, ultra-fast cache hierarchy for frequent lookups, distributed memory management for large context windows, and optimized memory controllers for model parameter access.

Embodiment 23. The method of embodiment 18 wherein the carbon modeling system further comprises an interconnect system having one or more of high-speed interconnects between AI accelerators, direct memory access channels, low-latency network fabric, and dedicated model pipeline buses.

Embodiment 24. The method of embodiment 18 wherein the carbon modeling system further comprises a multi-modal input processing engine for implementing specialized parsers for diverse input types.

Embodiment 25. The method of embodiment 18 wherein the carbon modeling system further comprises a scale-adaptive modeling framework for handling processes across multiple scales.

Embodiment 26. The method of embodiment 18 wherein the carbon modeling system has adaptive resolution modeling for dynamically adjusting model detail.

Embodiment 27. The method of embodiment 18 wherein the carbon modeling system has intelligent data extraction for machine learning models.

Embodiment 28. The method of embodiment 18 wherein the carbon modeling system has a cross-scale consistency engine for maintaining mathematical and physical consistency.

Embodiment 29. The method of embodiment 18 wherein the carbon modeling system is for generating a structured carbon system model comprising interconnected process nodes; material and energy flows; carbon impact calculations; and data quality indicators.

Embodiment 30. The method of embodiment 18 wherein the carbon modeling system further comprises a multi-modal input processor configured to: parse diverse input formats; extract structured data; validate input quality; and standardize data formats.

Embodiment 31. The method of embodiment 18 wherein the carbon modeling system further comprises a machine learning engine trained to: identify system components; map relationships; scale models appropriately; and maintain consistency.

Embodiment 32. The method of embodiment 18 wherein the carbon modeling system further comprises a data quality management subsystem configured to score data quality; track uncertainty; validate against standards; and monitor temporal relevance.

Embodiment 33. The method of embodiment 18 wherein the carbon modeling system further comprises a model generation engine configured to: create system models; validate calculations; ensure completeness; and maintain version control.

Embodiment 34. The method of embodiment 18 wherein the carbon modeling system further comprises a data quality visualization interface configured to display quality scores; highlight uncertainty; show validation status; and track quality improvements.

Embodiment 35. A computer-implemented method for automated carbon system modeling, said method comprising:
receiving, by one or more processors, multi-modal input data describing a carbon system, wherein the multi-modal input data comprises two or more of: structured data files; document images; process diagrams; real-time sensor data; natural language descriptions; and computer-aided design files;
analyzing, by a data quality assessment engine, the received multi-modal input data to: determine data quality scores for each input; identify data gaps and inconsistencies; validate data against reference standards; and assign confidence levels to derived values;
processing, by a machine learning model, the validated input data to: extract system components and relationships; identify process flows and dependencies;
determine system boundaries and scales; and map extracted elements to standardized templates;
generating, by the one or more processors, a structured carbon system model comprising: interconnected process nodes; material and energy flows; carbon impact calculations; and data quality indicators;
validating, by a model validation engine, the generated carbon system model by: verifying conservation of mass and energy; checking compliance with carbon accounting standards; confirming completeness of required elements; and assessing model uncertainty based on input data quality; and
storing the validated carbon system model in a distributed database system with: version control; audit trail; data quality metadata; and uncertainty quantification.

Embodiment 36. The method of embodiment 35, wherein the data quality assessment engine implements: data completeness scoring; temporal relevance evaluation; source reliability assessment; consistency checking; uncertainty quantification; and anomaly detection.

Embodiment 37. The method of embodiment 35, further comprising:
maintaining a continuous data quality score for each system component;
propagating uncertainty through calculations;
flagging components requiring additional validation;
suggesting data quality improvements; and
recording data quality lineage.

Embodiment 38. A system for automated carbon modeling comprising:
a multi-modal input processor configured to: parse diverse input formats; extract structured data; validate input quality; and standardize data formats;
a machine learning engine trained to: identify system components; map relationships; scale models appropriately; and maintain consistency;
a data quality management subsystem configured to: score data quality; track uncertainty; validate against standards; and monitor temporal relevance;
a model generation engine configured to: create system models; validate calculations; ensure completeness; and maintain version control.

Embodiment 39. The system of embodiment 38, further comprising a data quality visualization interface configured to: display quality scores; highlight uncertainty; show validation status; and track quality improvements.

Embodiment 40. The system of embodiment 38, wherein the data quality assessment engine is further configured to: validate environmental measurement methodologies; track calibration status of monitoring equipment; apply standard-specific quality protocols; maintain chain of custody for environmental data; and record verification status of measurements.

Embodiment 41. The system of embodiment 38, further comprising a specialized environmental data processor configured to: handle continuous emissions monitoring data; process environmental sample analyses; validate against environmental standards; track regulatory compliance status; and maintain verification documentation

Embodiment 42. The system of embodiment 38, wherein the model validation engine implements: environmental standard compliance checking; regulatory threshold monitoring; permit limit validation; compliance status tracking; and verification documentation management.

Embodiment 43. The system of embodiment 38, configured for manufacturing operations, further comprising: real-time production monitoring; material flow tracking; energy consumption analysis; process efficiency calculation; and quality-controlled emissions factors.

Embodiment 44. The system of embodiment 38, configured for transportation services, comprising: fleet operation monitoring; route optimization analysis; fuel consumption tracking; maintenance impact assessment; and modal shift analysis.

Embodiment 45. The system of embodiment 38, configured for building operations, comprising: energy management system integration; occupancy pattern analysis; HVAC system monitoring; utility data validation; and building performance metrics.

Embodiment 46. The system of embodiment 38, configured for agricultural operations, comprising: seasonal data normalization; weather impact analysis; soil carbon monitoring; biomass calculation; and fertilizer impact tracking.

Embodiment 47. The system of embodiment 38, configured for financial services, comprising: digital service carbon tracking; office operation monitoring; travel impact calculation; supply chain assessment; and investment portfolio analysis,

Embodiment 48. A method for managing data quality in carbon systems, comprising:
implementing continuous quality monitoring;
calculating quality-weighted metrics;
tracking quality improvement actions;
managing quality documentation; and
maintaining quality audit trails.

Embodiment 49. The method of embodiment 48, further comprising: setting quality thresholds by data type;
implementing quality improvement workflows;
tracking quality trends over time;
managing quality exceptions; and
reporting quality metrics.

Embodiment 50. The system of embodiment 35, which is an AI-powered system for trusted accounting, recording, tracking, and displaying embodied carbon dioxide equivalent (CO2e) or greenhouse gas (GHG) associated with producing a product or service, over the cradle to gate life cycle of the product or service.

Embodiment 51. A system comprising input and a memory including non-transitory program memory for storing at least instructions and a processor that is operative to execute instructions that enable actions, the system comprising:
a system that uses a layered AI-based integration comprising a natural language processing (NLP) interface, a large language model (LLM) abstraction layer, and a dynamic visualization module; wherein the system is configured to generate extensible carbon objects representing real world products and services including the use of carbon instruments and related environmental certificates comprising an application programming interface (API) gateway between a logical layer and a representational layer, the API gateway server being configured with an extensible Carbon Reporting Markup Language (<CarML>) configured to interface software with the logical layer, the <CarML> comprising a core set of common data schema and message types including interface objects for extensible carbon objects and third party external systems, the API gateway configured to allow the user to generate the extensible carbon objects representing carbon instruments;
a registry;
an interface to a legacy registry systems for tracking carbon instruments, environmental certificates, or other related carbon data,
a platform comprising a ledger configured for tracking, aggregating, accounting, recording, and assigning extensible carbon objects for carbon instruments, the trading platform comprising:
   an interface tool for transacting for carbon instruments;
   wherein the ledger is a distributed immutable ledger or blockchain; and
wherein the distributed immutable ledger or blockchain is configured to record an extensible carbon object digital twin comprising an embodied carbon dioxide equivalent (CO2e) or greenhouse gas (GHG) cradle to gate life cycle inventory (LCI) associated with a real world product or service, at a real world product or service scale or level ranging from large or industrial CO2e or GHG increments to small or individual CO2e or GHG increments.

Embodiment 52. The system of embodiment 51, wherein the ledger is configured to:
accept a carbon transaction comprising an extensible carbon object including a carbon offset, credit, removal, environmental certificate, or environmental instrument for the embodied CO2e or GHG LCI;
record the carbon offset to generate a lower embodied CO2e or GHG LCI object;
record a transfer of the lower carbon LCI to another entity; and
record a retirement of the lower embodied CO2e or GHG LCI.

Embodiment 53. The system of embodiment 51 which is configured to generate a report or assignable public certificate of the embodied CO2e or GHG over a cradle to gate life cycle of the carbon object associated with a real world product or service.

Embodiment 54. The system of embodiment 51 wherein the system comprises a Defined Unit Inventory configured to inventory a Defined Unit for a tenant member user entity as a digital twin of a real world product or service, the Defined Unit being configured to deplete as an input, wherein the Defined Unit is configured to be inputted and outputted across a plurality of tenant member user entities carbon adding processes as a concatenation of carbon process data, the Defined Unit Inventory comprising environmental carbon attribute data, and the system is configured to execute instructions to at least:
to initiate a transfer of ownership of a defined object from a tenant member Defined Unit inventory to another tenant member entity Defined Unit inventory;
record the Defined Unit transfer to the distributed immutable ledger or blockchain.

Embodiment 55. The system of embodiment 54 wherein the initiate transfer operation is configured to place the Defined Unit object certificate in a transfer state for the Defined Unit object certificate transfer.

Embodiment 56. The system of embodiment 55 wherein the Defined Unit transfer state digital embodied CO2e or GHG twin certificate comprises a plurality of transfer states including an open market offered state, a transfer to another part initiated state, a pending transfer state, and an accepted transfer state, wherein the recipient takes legal possession of the assignable environmental embodiments associated with the certificate.

Embodiment 57. The system of embodiment 56 wherein the system is configured to change an object owner attribute for on object when the Defined Unit is legally transferred from tenant to another tenant, and publicly registered in the system, with the system acting as a public system of record.

Embodiment 58. The system of embodiment 51, further comprising:
a logical layer comprising a plurality of library modules for monitoring and tracking embodied CO2e or GHG emissions, including:
   a Process Library comprising a user interface to an external client
   a Reference Unit Library comprising an extensible absolute unit reference manager to instantiate and store a Reference Unit object, the Reference Unit object comprising a unit of embodied CO2e or GHG emission associated datum, the Reference Unit Library comprising a conversion algorithm configured to convert data values to base units associated with the Reference Units;
   an Attribute Library comprising a plurality of extensible attribute objects configured to include a plurality of attribute dimensions including a dimensional structure for the Reference Units and the Defined Units, the attribute dimensions comprising the environmental carbon attribute data.
   a LCI library database configured to store an environmental embodied CO2e or GHG record for the cradle to gate life cycle of an item or process, based on the process inputs and outputs of the Reference Units and the Defined Units;
   a searchable greenhouse gas equivalence database and reporting module;
a relational database comprising a database for carbon data transactions;
a distributed immutable ledger or blockchain;
a conversion library comprising extensible conversion information for the environmental carbon equivalence attribute data;
a display layer interface comprising
   a display manager user interface configured to allow a user to input data to a storage and compute layer; and
   a report manager, the report manager being configured to generate an embodied CO2e or GHG life cycle report or assignable certificate twinned with an item or process, as a structured data object and a machine-readable code associated with a Defined Unit.

Embodiment 59. A method of aggregating, gathering, accounting, recording, tracking, and/or displaying embodied carbon dioxide equivalent (CO2e) or greenhouse gas (GHG) of a product or service as a report or assignable certificate recorded in a registry, said method comprising:
providing system comprising input and a memory including non-transitory program memory for storing at least instructions and a processor that is operative to execute instructions that enable actions; an application programming interface (API) gateway between a logical layer and a representational layer, the API gateway server being configured with an extensible Carbon Reporting Markup Language (<CarML>) configured to interface software with the logical layer, the <CarML> comprising a core set of common data schema and message types including interface objects for extensible carbon objects and third party external systems, the API gateway configured to allow the user to generate the extensible carbon objects representing carbon instruments; a registry; an interface to a registry system for tracking carbon instruments, environmental certificates, or other related carbon data; and a platform comprising a distributed immutable ledger or blockchain having an interface tool for transacting for carbon instruments; wherein the system uses a layered AI-based integration comprising a natural language processing (NLP) interface, a large language model (LLM) abstraction layer, and a dynamic visualization module;
configuring the system to generate extensible carbon objects representing real world products and services including the use of carbon instruments and related environmental certificates;
configuring the platform for tracking and assigning extensible carbon objects representing carbon instruments;
configuring the distributed immutable ledger or blockchain to record an extensible carbon object digital twin comprising an embodied carbon dioxide equivalent (CO2e) or greenhouse gas (GHG) cradle to gate life cycle inventory (LCI) associated with a real world product or service, at a real world product or service scale or level ranging from large or industrial CO2e or GHG increments to small or individual CO2e or GHG increments; and
configuring a report manager to generate an embodied CO2e or GHG life cycle of a product or service as a structured data object report or assignable certificate which has a machine-readable code associated with a Defined Unit, and recorded in the registry.

Embodiment 60. The method of embodiment 59, further comprising configuring the distributed immutable ledger or blockchain to:
accept a carbon transaction comprising an extensible carbon object including a carbon offset, credit, removal, environmental certificate, or environmental instrument for the embodied CO2e or GHG LCI;
record the carbon offset to generate a lower embodied CO2e or GHG LCI object;
record a transfer of the lower carbon LCI to another entity; and
record a retirement of the lower embodied CO2e or GHG LCI.

Embodiment 61. The method of embodiment 59 further comprising configuring the system to generate a report or assignable public certificate of the embodied CO2e or GHG over a cradle to gate life cycle of the carbon object associated with a real world product or service, recorded in the registry.

Embodiment 62. The method of embodiment 59 wherein the system further comprises a Defined Unit Inventory comprising environmental carbon attribute data.

Embodiment 63. The method of embodiment 62 further comprising:
configuring the Defined Unit Inventory to inventory a Defined Unit for a tenant member user entity as a digital twin of a real world product or service;
configuring the Defined Unit to deplete as an input;
configuring the Defined Unit to be inputted and outputted across a plurality of tenant member user entities, carbon adding processes, as a concatenation of carbon process data, the Defined Unit Inventory comprising environmental carbon attribute data; and
configuring the system to execute instructions to at least:
to initiate a transfer of ownership of a defined object from a tenant member Defined Unit inventory to another tenant member entity Defined Unit inventory; and
record the Defined Unit transfer to the distributed immutable ledger or blockchain.

Embodiment 64. The method of embodiment 63 further comprising configuring the initiate transfer operation to place the Defined Unit object certificate in a transfer state for the Defined Unit object certificate transfer.

Embodiment 65. The method of embodiment 64 wherein the Defined Unit transfer state digital embodied CO2e or GHG twin certificate comprises a plurality of transfer states including an open market offered state, a transfer to another part initiated state, a pending transfer state, and an accepted transfer state, wherein the recipient takes legal possession of the assignable environmental embodiments associated with the certificate.

Embodiment 66. The method of embodiment 64 further comprising configuring the system to change an object owner attribute for on object when the Defined Unit is legally transferred from tenant to another tenant, and publicly registered in the system, with the system acting as a public system of record.

Embodiment 67. The method of embodiment 59, wherein the system further comprises:
a logical layer comprising a plurality of library modules for monitoring and tracking embodied CO2e or GHG emissions, including:
   a Process Library comprising a user interface to an external client;
   a Reference Unit Library comprising an extensible absolute unit reference manager to instantiate and store a Reference Unit object, the Reference Unit object comprising a unit of embodied CO2e or GHG emission associated datum, the Reference Unit Library comprising a conversion algorithm;
   an Attribute Library comprising a plurality of extensible attribute objects;
   a LCI library database;
   a searchable greenhouse gas equivalence database and reporting module;
a relational database comprising a database for carbon data transactions;
a distributed immutable ledger or blockchain;
a conversion library comprising extensible conversion information for the environmental carbon equivalence attribute data;
a display layer interface comprising
   a display manager user interface; and
   a report manager.

Embodiment 68. The method of embodiment 67, further comprising:
configuring the conversion algorithm to convert data values to base units associated with the Reference Units;
configuring the Attribute Library to include a plurality of attribute dimensions including a dimensional structure for the Reference Units and the Defined Units, the attribute dimensions comprising the environmental carbon attribute data;
configuring the LCI library database to store an environmental embodied CO2e or GHG record for the cradle to gate life cycle of an item or process, based on the process inputs and outputs of the Reference Units and the Defined Units;
configuring the display manager user interface to allow a user to input data to a storage and compute layer; and
configuring the report manager to generate an embodied CO2e or GHG life cycle report or assignable certificate twinned with an item or process, as a structured data object and a machine-readable code associated with a Defined Unit.

What is claimed is:

1. A carbon modeling system that uses a layered AI-based integration, said carbon modeling system comprising a natural language processing (NLP) interface, a large language model (LLM) abstraction layer, and a dynamic visualization module, wherein said system is capable of producing interactive carbon emissions estimations for user-described processes.

2. The carbon modeling system of claim 1 wherein the layered AI-based integration comprises one or more AI processing units having dedicated AI accelerator ASICs optimized for transformer model operations, neural Processing Units (NPUs) for real-time natural language processing, tensor Processing Units (TPUs) for parallel matrix computations, and graphics processing unit (GPU) clusters for distributed model inference.

3. The carbon modeling system of claim 1 further comprising multi-modal input processing hardware having one or more document scanning and optical character recognition (OCR) acceleration units, image processing arrays for technical diagram parsing, specialized digital signal processing (DSPs) for industrial sensor data processing, and real-time streaming data processors.

4. The carbon modeling system of claim 1 further comprising a model execution pipeline having one or more of hardware-optimized transformer blocks, dedicated attention mechanism processors, parallel inference engines, and low-latency model serving units.

5. The carbon modeling system of claim 1 further comprising memory architecture having one or more of high-bandwidth memory (HBM) for model weights, ultra-fast cache hierarchy for frequent lookups, distributed memory management for large context windows, and optimized memory controllers for model parameter access.

6. The carbon modeling system of claim 1 further comprising an interconnect system having one or more of high-speed interconnects between AI accelerators, direct memory access channels, low-latency network fabric, and dedicated model pipeline buses.

7. The carbon modeling system of claim 1 for generating a structured carbon system model comprising interconnected process nodes; material and energy flows; carbon impact calculations; and data quality indicators.

8. A computer-implemented method for automated carbon system modeling, said method comprising:
receiving, by one or more processors, multi-modal input data describing a carbon system, wherein the multi-modal input data comprises two or more of: structured data files; document images; process diagrams; real-time sensor data; natural language descriptions; and computer-aided design files;
analyzing, by a data quality assessment engine, the received multi-modal input data to: determine data quality scores for each input; identify data gaps and inconsistencies; validate data against reference standards; and assign confidence levels to derived values;
processing, by a machine learning model, the validated input data to: extract system components and relationships; identify process flows and dependencies;
determine system boundaries and scales; and map extracted elements to standardized templates;
generating, by the one or more processors, a structured carbon system model comprising: interconnected process nodes; material and energy flows; carbon impact calculations; and data quality indicators;
validating, by a model validation engine, the generated carbon system model by: verifying conservation of mass and energy; checking compliance with carbon accounting standards; confirming completeness of required elements; and assessing model uncertainty based on input data quality; and
storing the validated carbon system model in a distributed database system with: version control; audit trail; data quality metadata; and uncertainty quantification.

9. The method of claim 8, wherein the data quality assessment engine implements: data completeness scoring; temporal relevance evaluation; source reliability assessment; consistency checking; uncertainty quantification; and anomaly detection.

10. The method of claim 8, further comprising:
maintaining a continuous data quality score for each system component;
propagating uncertainty through calculations;
flagging components requiring additional validation;
suggesting data quality improvements; and
recording data quality lineage.

11. A system for automated carbon modeling comprising:
a multi-modal input processor configured to: parse diverse input formats; extract structured data; validate input quality; and standardize data formats;
a machine learning engine trained to: identify system components; map relationships; scale models appropriately; and maintain consistency;
a data quality management subsystem configured to: score data quality; track uncertainty; validate against standards; and monitor temporal relevance;
a model generation engine configured to: create system models; validate calculations; ensure completeness; and maintain version control.

12. The system of claim 11, wherein the data quality assessment engine is further configured to: validate environmental measurement methodologies; track calibration status of monitoring equipment; apply standard-specific quality protocols; maintain chain of custody for environmental data; and record verification status of measurements.

13. The system of claim 11, further comprising a specialized environmental data processor configured to: handle continuous emissions monitoring data; process environmental sample analyses; validate against environmental standards; track regulatory compliance status; and maintain verification documentation.

14. The system of claim 11, configured for manufacturing operations, further comprising: real-time production monitoring; material flow tracking; energy consumption analysis; process efficiency calculation; and quality-controlled emissions factors.

15. The system of claim 11, configured for financial services, comprising: digital service carbon tracking; office operation monitoring; travel impact calculation; supply chain assessment; and investment portfolio analysis,

16. A system comprising input and a memory including non-transitory program memory for storing at least instructions and a processor that is operative to execute instructions that enable actions, the system comprising:
a system that uses a layered AI-based integration comprising a natural language processing (NLP) interface, a large language model (LLM) abstraction layer, and a dynamic visualization module; wherein the system is configured to generate extensible carbon objects representing real world products and services including the use of carbon instruments and related environmental certificates comprising an application programming interface (API) gateway between a logical layer and a representational layer, the API gateway server being configured with an extensible Carbon Reporting Markup Language (<CarML>) configured to interface software with the logical layer, the <CarML> comprising a core set of common data schema and message types including interface objects for extensible carbon objects and third party external systems, the API gateway configured to allow the user to generate the extensible carbon objects representing carbon instruments;
a registry;
an interface to a legacy registry systems for tracking carbon instruments, environmental certificates, or other related carbon data,
a platform comprising a ledger configured for tracking, aggregating, accounting, recording, and assigning extensible carbon objects for carbon instruments, the trading platform comprising:
an interface tool for transacting for carbon instruments;
wherein the ledger is a distributed immutable ledger or blockchain; and
wherein the distributed immutable ledger or blockchain is configured to record an extensible carbon object digital twin comprising an embodied carbon dioxide equivalent (CO2e) or greenhouse gas (GHG) cradle to gate life cycle inventory (LCI) associated with a real world product or service, at a real world product or service scale or level ranging from large or industrial CO2e or GHG increments to small or individual CO2e or GHG increments.

17. The system of claim 16, wherein the ledger is configured to:
accept a carbon transaction comprising an extensible carbon object including a carbon offset, credit, removal, environmental certificate, or environmental instrument for the embodied CO2e or GHG LCI;
record the carbon offset to generate a lower embodied CO2e or GHG LCI object;
record a transfer of the lower carbon LCI to another entity; and
record a retirement of the lower embodied CO2e or GHG LCI.

18. The system of claim 16 wherein the system comprises a Defined Unit Inventory configured to inventory a Defined Unit for a tenant member user entity as a digital twin of a real world product or service, the Defined Unit being configured to deplete as an input, wherein the Defined Unit is configured to be inputted and outputted across a plurality of tenant member user entities carbon adding processes as a concatenation of carbon process data, the Defined Unit Inventory comprising environmental carbon attribute data, and the system is configured to execute instructions to at least:
to initiate a transfer of ownership of a defined object from a tenant member Defined Unit inventory to another tenant member entity Defined Unit inventory;
record the Defined Unit transfer to the distributed immutable ledger or blockchain.

19. The system of claim 16 wherein a Defined Unit transfer state digital embodied CO2e or GHG twin certificate comprises a plurality of transfer states including an open market offered state, a transfer to another part initiated state, a pending transfer state, and an accepted transfer state, wherein the recipient takes legal possession of the assignable environmental claims associated with the certificate.

20. The system of claim 16, further comprising:
a logical layer comprising a plurality of library modules for monitoring and tracking embodied CO2e or GHG emissions, including:
a Process Library comprising a user interface to an external client
a Reference Unit Library comprising an extensible absolute unit reference manager to instantiate and store a Reference Unit object, the Reference Unit object comprising a unit of embodied CO2e or GHG emission associated datum, the Reference Unit Library comprising a conversion algorithm configured to convert data values to base units associated with the Reference Units;
an Attribute Library comprising a plurality of extensible attribute objects configured to include a plurality of attribute dimensions including a dimensional structure for the Reference Units and the Defined Units, the attribute dimensions comprising the environmental carbon attribute data.
a LCI library database configured to store an environmental embodied CO2e or GHG record for the cradle to gate life cycle of an item or process, based on the process inputs and outputs of the Reference Units and the Defined Units;
a searchable greenhouse gas equivalence database and reporting module;
a relational database comprising a database for carbon data transactions;
a distributed immutable ledger or blockchain;
a conversion library comprising extensible conversion information for the environmental carbon equivalence attribute data;
a display layer interface comprising
a display manager user interface configured to allow a user to input data to a storage and compute layer; and
a report manager, the report manager being configured to generate an embodied CO2e or GHG life cycle report or assignable certificate twinned with an item or process, as a structured data object and a machine-readable code associated with a Defined Unit.

21. A method of aggregating, gathering, accounting, recording, tracking, and/or displaying embodied carbon dioxide equivalent (CO2e) or greenhouse gas (GHG) of a product or service as a report or assignable certificate recorded in a registry, said method comprising:
providing system comprising input and a memory including non-transitory program memory for storing at least instructions and a processor that is operative to execute instructions that enable actions; an application programming interface (API) gateway between a logical layer and a representational layer, the API gateway server being configured with an extensible Carbon Reporting Markup Language (<CarML>) configured to interface software with the logical layer, the <CarML> comprising a core set of common data schema and message types including interface objects for extensible carbon objects and third party external systems, the API gateway configured to allow the user to generate the extensible carbon objects representing carbon instruments; a registry; an interface to a registry system for tracking carbon instruments, environmental certificates, or other related carbon data; and a platform comprising a distributed immutable ledger or blockchain having an interface tool for transacting for carbon instruments; wherein the system uses a layered AI-based integration comprising a natural language processing (NLP) interface, a large language model (LLM) abstraction layer, and a dynamic visualization module;
configuring the system to generate extensible carbon objects representing real world products and services including the use of carbon instruments and related environmental certificates;
configuring the platform for tracking and assigning extensible carbon objects representing carbon instruments;
configuring the distributed immutable ledger or blockchain to record an extensible carbon object digital twin comprising an embodied carbon dioxide equivalent (CO2e) or greenhouse gas (GHG) cradle to gate life cycle inventory (LCI) associated with a real world product or service, at a real world product or service scale or level ranging from large or industrial CO2e or GHG increments to small or individual CO2e or GHG increments; and
configuring a report manager to generate an embodied CO2e or GHG life cycle of a product or service as a structured data object report or assignable certificate which has a machine-readable code associated with a Defined Unit, and recorded in the registry.

22. The system of claim 1, further comprising a generative optimization engine configured to:
automatically identify nodes within the interactive node graph exceeding a pre-defined carbon intensity threshold;
query the large language model (LLM) to retrieve functionally equivalent low-carbon alternatives for said nodes; and
automatically regenerate the node graph to display a solved optimized scenario comprising said low-carbon alternatives.

23. The system of claim 1, further configured to generate a marginal abatement cost curve (MACC) visualization, wherein the system:
retrieves cost data associated with the user-described processes and identified low-carbon alternatives;
calculates a marginal abatement cost for each alternative relative to the baseline; and
generates a visual interface ranking said alternatives by cost-efficiency, allowing the user to select a subset of alternatives to solve for a specific carbon reduction target or financial budget.

24. The method of claim 21, wherein the system further comprises a generative optimization engine configured to:
automatically identify nodes within the interactive node graph exceeding a pre-defined carbon intensity threshold;
query the large language model (LLM) to retrieve functionally equivalent low-carbon alternatives for said nodes; and
automatically regenerate the node graph to display a solved optimized scenario comprising said low-carbon alternatives.

25. The method of claim 21, further configured to generate a marginal abatement cost curve (MACC) visualization, wherein the system:
retrieves cost data associated with the user-described processes and identified low-carbon alternatives;
calculates a marginal abatement cost for each alternative relative to the baseline; and
generates a visual interface ranking said alternatives by cost-efficiency, allowing the user to select a subset of alternatives to solve for a specific carbon reduction target or financial budget.
